(19) United States
(12) Patent Application Publication
(10) Pub. No.: US 2014/0021036 A1
(43) Pub. Date: Jan. 23, 2014

(54) SPUTTERING TARGET, METHOD FOR USING THE SAME, AND METHOD FOR FORMING OXIDE FILM

(71) Applicant: Semiconductor Energy Laboratory Co., Ltd., Atsugi-shi (JP)

(72) Inventor: Shunpei YAMAZAKI, Setagaya (JP)

(21) Appl. No.: 13/942,263

(22) Filed: Jul. 15, 2013

(30) Foreign Application Priority Data
Jul. 19, 2012 (JP) 2012-160570

(51) Int. Cl. C23C 14/34

(52) U.S. Cl. CPC C23C 14/3407
USPC 204/192.1; 204/298.13

(57) ABSTRACT

To provide a sputtering target which enables an In—Zn oxide film with a high degree of crystallinity to be formed and a method for using the sputtering target. The sputtering target includes a polycrystalline In—Zn oxide containing a plurality of crystal grains whose average grain size is greater than or equal to 0.06 μm and less than or equal to 3 μm. Further, the crystal grains each have a cleavage plane, and as the method for using the sputtering target, sputtered particles are separated from the cleavage planes by collision of an ion with the sputtering target, and the sputtered particles are positively charged and deposited on a deposition surface uniformly while repelling with each other.

### BACKGROUND OF THE INVENTION

1. Field of the Invention

The present invention relates to a sputtering target and a manufacturing method thereof. In addition, the present invention relates to an oxide film formed by a sputtering method with use of the sputtering target, and a semiconductor device including the oxide film.

In this specification, a semiconductor device generally refers to a device which can function by utilizing semiconductor characteristics; an electro-optical device, a semiconductor circuit, and an electronic device are all included in the category of the semiconductor device.

2. Description of the Related Art

In recent years, a technique by which transistors are formed using semiconductor thin films formed over a substrate having an insulating surface has been attracting attention. The transistor is applied to a wide range of electronic devices such as an integrated circuit (IC) or an image display device (display device). A silicon film is widely known as a semiconductor thin film applicable to the transistor. As another material, an oxide semiconductor film has been attracting attention.

For example, a transistor including an amorphous oxide semiconductor film that contains indium (In), gallium (Ga), and zinc (Zn) and has an electron carrier density lower than 10¹⁸/cm³ is disclosed. As a method for forming the amorphous oxide semiconductor film, a sputtering method is considered the most suitable (see Patent Document 1).

In addition, a transistor including an amorphous oxide semiconductor film that contains In and Zn is disclosed (see Patent Document 2).

An oxide semiconductor film containing In and Zn has a high controllability of carrier density, but there have been a problem in that the oxide semiconductor film easily becomes amorphous and its physical properties are unstable.

On the other hand, there is a report that a transistor including a crystalline oxide semiconductor film has more excellent electric characteristics and higher reliability than a transistor including an amorphous oxide semiconductor film (see Non-Patent Document 1).

### REFERENCE

### Patent Document

[Patent Document 1] Japanese Published Patent Application No. 2006-165528
[Patent Document 2] Japanese Published Patent Application No. 2010-018479

### Non-Patent Document

[Non-Patent Document 1] Shunpei Yamazaki, Jun Koyama, Yoshitaka Yamamoto, and Kenji Okamoto, “Research, Development, and Application of Crystalline Oxide Semiconductor”, SID 2012 DIGEST, pp. 183-186

### SUMMARY OF THE INVENTION

An object is to provide a method for forming an In—Zn oxide film, particularly a method for forming a crystalline In—Zn oxide film.

Another object is to provide a sputtering target which enables the In—Zn oxide film to be formed.

Another object is to provide a method for using the sputtering target.

Another object is to provide a transistor which includes an In—Zn oxide film and has stable electric characteristics.

Another object is to provide a highly reliable semiconductor device including the transistor.

One embodiment of the present invention is a sputtering target including a polycrystalline In—Zn oxide containing a plurality of crystal grains whose average grain size is less than or equal to 3 μm.

Further, the plurality of crystal grains each have a cleavage plane. The cleavage plane indicates a plane where bonding of atoms or molecules constituting the crystal grain is weak (i.e., a plane where cleavage occurs or a plane which is easily cleaved). Note that the size of the crystal grain can be measured by an electron backscatter diffraction method.

Another embodiment of the present invention is a method for using a sputtering target including a polycrystalline In—Zn oxide, in which a plurality of flat-plate-like sputtered particles which are separated from the sputtering target and positively charged are deposited on a deposition surface (a surface where a film is to be formed) while repelling with each other.

Another embodiment of the present invention is a method for using a sputtering target including a polycrystalline In—Zn oxide, in which a plurality of flat-plate-like sputtered particles are separated from the sputtering target by collision of an ion with the sputtering target, and the sputtered particles are positively charged and deposited on a deposition surface while repelling with each other.

Another embodiment of the present invention is a method for using a sputtering target including a polycrystalline In—Zn oxide containing a plurality of crystal grains whose average grain size is less than or equal to 3 μm, in which the crystal grains each have a cleavage plane, sputtered particles are separated from the cleavage planes by collision of an ion with the sputtering target, and the sputtered particles are positively charged and deposited on a deposition surface while repelling with each other.

The sputtered particles preferably have a hexagonal cylinder shape, which facilitates uniform deposition of the sputtered particles. Thus, the crystal grains are preferably hexagonal crystals. In the case where the plurality of crystal grains are hexagonal crystals, the sputtered particle separated from a cleavage plane has a hexagonal cylinder shape whose top and bottom surfaces are approximately equilateral hexagons each having an interior angle of 120°. Note that the crystal grains may be trigonal crystals.

Another embodiment of the present invention is a method for forming an In—Zn oxide film, in which sputtered particles are deposited by any of the above methods.

The sputtered particle which is formed by partly separating the crystal grain in the above manner has high crystallinity. The separated sputtered particle reaches a deposition surface and is deposited thereon; thus, an In—Zn oxide film with a high degree of crystallinity can be formed.

When an ion collides with the sputtering target including a plurality of crystal grains whose average grain size is less than or equal to 3 μm, a particle that is to be a sputtered particle can be separated from a cleavage plane of the crystal grain.

Note that the sputtered particle is separated from the cleavage plane and thus has a flat plate-like shape (also referred to as a pellet shape). As obvious in terms of stability, the flat plate-like sputtered particle is attached to a deposition surface with a high probability that the cleavage plane (flat surface) and the deposition surface are parallel to each other. Thus, a crystal part of an In—Zn oxide film to be formed is aligned along one crystal axis. For example, in the case where a cleavage plane of a crystal grain is parallel to an a-b plane, a crystal part of an In—Zn oxide film has c-axis alignment. That is, a normal vector of the deposition surface and the c-axis of the crystal part included in the In—Zn oxide film are parallel to each other. However, an a-axis is freely rotated on the c-axis; therefore, the directions of a-axes of a plurality of crystal parts included in the In—Zn oxide film are not the same.

Although ideally, sputtered particles are single crystals, crystallinity of part of the sputtered particles may be lowered due to the impact of ion collision and the like. Thus, in some cases, an In—Zn oxide film that is to be formed includes a region with low crystallinity between crystal parts. Note that owing to the region with low crystallinity between the crystal parts, a grain boundary in the In—Zn oxide film is unclear. For example, in a transmission electron microscope (TEM) image, a boundary between crystal parts, that is, a grain boundary is not clearly observed. Thus, in an In—Zn oxide film according to one embodiment of the present invention, a reduction in electron mobility due to the grain boundary is suppressed, and accordingly the In—Zn oxide film has high electron mobility.

The relative density of the sputtering target is preferably higher than or equal to 90%, higher than or equal to 95%, or higher than or equal to 99%. Note that the relative density of the sputtering target refers to a ratio between the density of the sputtering target and the density of a substance which is free of porosity and has the same composition as the sputtering target.

Below is described a method for increasing the degree of crystallinity of an In—Zn oxide film which is formed by depositing sputtered particles by using any of the above methods.

By reducing the amount of impurities that enter an In—Zn oxide film that is to be formed, a crystal state is prevented from being disordered by the impurities, and thus an In—Zn oxide film with a high degree of crystallinity can be formed. For example, the concentration of impurities (e.g., hydrogen, water, carbon dioxide, or nitrogen) which exist in a film formation chamber may be reduced. Furthermore, the concentration of impurities in a deposition gas may be reduced. Specifically, a deposition gas whose dew point is −80° C. or lower, preferably −100° C. or lower is used.

Further, when the deposition surface has minute unevenness, the degree of crystallinity of an In—Zn oxide film is lowered. Thus, the planarity of the deposition surface is improved, whereby an In—Zn oxide film with a high degree of crystallinity can be formed.

Further, when the heating temperature during film formation is high, an In—Zn oxide film with a high degree of crystallinity can be formed. For example, the heating temperature during film formation may be higher than or equal to 100° C. and lower than or equal to 740° C., preferably higher than or equal to 200° C. and lower than or equal to 500° C. By increasing the heating temperature during the film formation, when the flat-plate-like sputtered particle reaches the deposition surface, migration occurs on the deposition surface, so that a cleavage plane of the flat-plate-like sputtered particle is likely to be attached to the deposition surface. As a result, an In—Zn oxide film with a high degree of crystallinity can be formed.

Further, when plasma damage generated during film formation is alleviated, an In—Zn oxide film with a high degree of crystallinity can be formed. Thus, the percentage of oxygen in a deposition gas is increased, and power is optimized, whereby an In—Zn oxide film with a high degree of crystallinity can be formed. For example, the percentage of oxygen in the deposition gas is set to be higher than or equal to 30 vol. %, preferably higher than or equal to 50 vol. %, further preferably higher than or equal to 80 vol. %, still further preferably higher than or equal to 100 vol. %.

In addition, by performing heat treatment after film formation, the degree of crystallinity of the In—Zn oxide film can be increased because the impurity concentration in the In—Zn oxide film can be reduced by the heat treatment. The heat treatment is highly effective in reducing the impurity concentration when performed in an inert atmosphere or a reduced-pressure atmosphere. Further, heat treatment in an oxidation atmosphere is preferably performed after the heat treatment in an inert atmosphere or a reduced-pressure atmosphere is performed. When heat treatment is performed in an inert atmosphere or a reduced-pressure atmosphere, as well as a reduction in the impurity concentration, oxygen vacancies are caused, in some cases, in the In—Zn oxide film. Thus, by performing the heat treatment in an oxidation atmosphere, the number of oxygen vacancies in the In—Zn oxide film can be reduced.

In the above manner, an In—Zn oxide film with a high degree of crystallinity can be formed.

In such an In—Zn oxide film with a high degree of crystallinity, c-axes of crystals are aligned. Such an oxide film is called a c-axis aligned crystalline oxide semiconductor (CAAC-OS) film.

The CAAC-OS film is one of oxide semiconductor films including a plurality of crystal parts, and most of the crystal parts each fits inside a cube whose one side is less than 100 nm. Thus, there is a case where a crystal part included in the CAAC-OS film fits inside a cube whose one side is less than 10 nm, less than 5 nm, or less than 3 nm. The density of defect states of the CAAC-OS film is lower than that of the microcrystalline oxide semiconductor film.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

Note that the crystal part is formed concurrently with deposition of the CAAC-OS film or is formed through crystallization treatment such as heat treatment. As described above, the c-axis of the crystal is aligned with a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

In this specification, the trigonal and rhombohedral crystal systems are included in the hexagonal crystal system.

In a transistor using the CAAC-OS film, change in electric characteristics of the transistor due to irradiation with visible light or ultraviolet light is small. Thus, the transistor has high reliability.

Thus, another embodiment of the present invention is a transistor including the In—Zn oxide film in which a channel is formed.

Further, another embodiment of the present invention is a semiconductor device including the transistor.

A sputtering target including a polycrystalline In—Zn oxide containing a plurality of crystal grains whose average grain size is less than or equal to 3 μm can be provided.

Further, an In—Zn oxide film with a high degree of crystallinity can be formed by making an ion collide with the sputtering target and separating part of the crystal grain from a cleavage plane.

Further, with an In—Zn oxide film with a high degree of crystallinity, a transistor with stable electric characteristics can be provided.

Further, a highly reliable semiconductor device including the transistor can be provided.

### BRIEF DESCRIPTION OF THE DRAWINGS

FIGS. 1A and 1B are flow charts showing an example of a method for manufacturing a sputtering target.

FIGS. 2A and 2B are schematic views illustrating sputtered particles separated from a sputtering target.

FIG. 3 is a schematic view illustrating a situation in which a sputtered particle reaches a deposition surface.

FIG. 4 is a top view illustrating an example of a film formation apparatus.

FIGS. 5A to 5C are cross-sectional views illustrating an example of a film formation chamber.

FIGS. 6A to 6D each illustrate a positional relation between sputtering targets, magnets, and a substrate holder.

FIGS. 7A to 7C are a top view and cross-sectional views illustrating an example of a transistor.

FIGS. 8A to 8C are a top view and cross-sectional views illustrating an example of a transistor.

FIGS. 9A to 9C are a top view and cross-sectional views illustrating an example of a transistor.

FIGS. 10A to 10C are a top view and cross-sectional views illustrating an example of a transistor.

FIGS. 11A and 11B are a top view and a cross-sectional view of a display device using an EL element according to one embodiment of the present invention, and

FIG. 11C is a circuit diagram of a pixel of the display device.

FIG. 12A is a cross-sectional view of a display device using a liquid crystal element according to one embodiment of the present invention, and FIG. 12B is a circuit diagram of a pixel of the display device.

FIGS. 13A to 13D each illustrate an electronic device according to one embodiment of the present invention.

FIG. 14A shows a crystal grain map of Sample, and FIG. 14B is a histogram of grain sizes thereof.

FIG. 15 is a graph showing crystal alignment of an In—Zn oxide film.

FIGS. 16A and 16B are a cross-section observation image of an In—Zn oxide film and an electron diffraction image thereof.

FIG. 17 is a schematic view illustrating a situation in which sputtered particles which are not charged reach a deposition surface.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details thereof can be modified in various ways. Therefore, the present invention is not construed as being limited to description of the embodiments. In describing structures of the present invention with reference to the drawings, the same reference numerals are used in common for the same portions in different drawings. Note that the same hatch pattern is applied to similar parts, and the similar parts are not especially denoted by reference numerals in some cases.

Note that the ordinal numbers such as “first” and “second” in this specification are used for convenience and do not denote the order of steps or the stacking order of layers. In addition, the ordinal numbers in this specification do not denote particular names which specify the present invention.

### Embodiment 1

In this embodiment, a sputtering target of one embodiment of the present invention will be described.

The relative density of the sputtering target is higher than or equal to 90%, higher than or equal to 95%, or higher than or equal to 99%.

The sputtering target includes a polycrystalline In—Zn oxide containing a plurality of crystal grains whose average grain size is less than or equal to 3 μm, preferably less than or equal to 2 μm, further preferably less than or equal to 1 μm.

Alternatively, the sputtering target includes a polycrystalline In—Zn oxide containing a plurality of crystal grains in which the proportion of crystal grains having a grain size greater than or equal to 0.06 μm and less than 1 μm, greater than or equal to 0.06 μm and less than 0.8 μm, or greater than or equal to 0.06 μm and less than 0.4 μm is higher than or equal to 20%, preferably higher than or equal to 50%, further preferably 80%.

Note that the grain size of the crystal grain can be measured by electron backscatter diffraction (EBSD). The grain size of the crystal grain described here is calculated from a cross-sectional area, assuming that a cross section of one crystal grain is a perfect circle. The cross section of the crystal grain can be measured from a crystal grain map obtained by EBSD. Specifically, when the cross-sectional area of the crystal grain is denoted by S and the radius of the cross section of the crystal grain is denoted by r, the radius r is calculated from a relation, S=πr² to obtain the grain size which can be represented by 2r (twice the radius r).

Further, the plurality of crystal grains included in the sputtering target have cleavage planes. The cleavage plane is a plane parallel to an a-b plane, for example.

Owing to small grain sizes of the plurality of crystal grains, when an ion collides with the crystal grain, a sputtered particle is separated from the cleavage plane. The separated sputtered particle has a flat plate-like shape whose top and bottom surfaces are parallel to the cleavage plane. Further, owing to small grain sizes of the plurality of crystal grains, arrangement of crystal grains is distorted and a sputtered particle becomes easily separated from the cleavage plane.

Note that when the plurality of crystal grains included in the sputtering target are hexagonal crystals, flat plate-like sputtered particles each have the shape of a hexagonal cylinder whose top and bottom surfaces are approximately equilateral hexagons each having internal angles of 120°.

Although sputtered particles are ideally single crystals, crystallinity of part of the sputtered particles may be lowered due to the impact of ion collision.

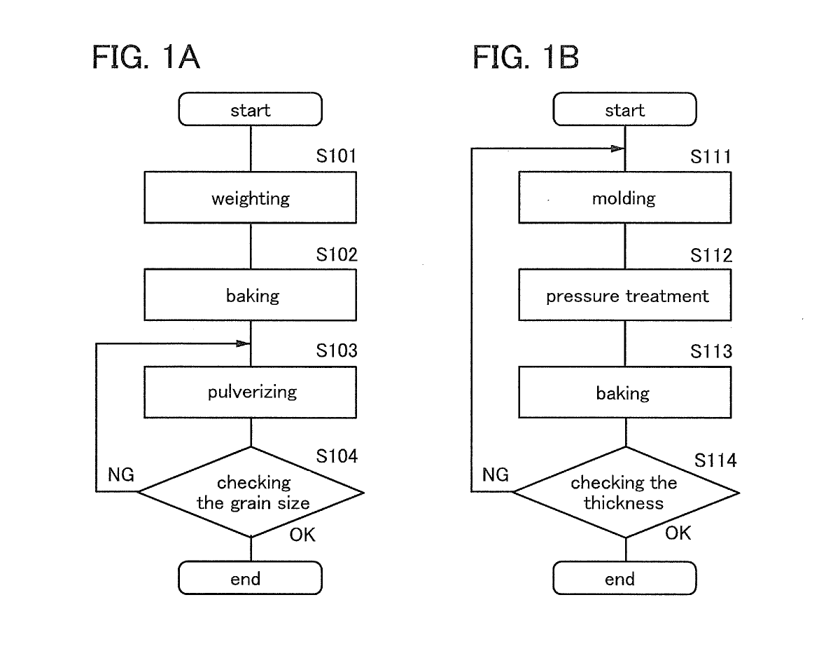

A method for forming the above sputtering target is described with reference to FIGS. 1A and 1B.

FIG. 1A shows formation of an In—Zn oxide powder to be a sputtering target. First, an indium oxide powder and a zinc oxide powder are weighted in a step S101.

Next, the indium oxide powder and the zinc oxide powder are mixed in a predetermined molar ratio. For example, the molar ratio between the indium oxide powder and the zinc oxide powder is set to 9:1, 2:1, 8:3, 3:1, 1:1, 4:3, 1:2, 3:4, or 3:2. With such a molar ratio, a sputtering target including a polycrystalline oxide with high crystallinity can be obtained easily later.

Next, in a step S102, an In—Zn oxide is obtained by performing first baking on the indium oxide powder and the zinc oxide powder which are mixed in a predetermined molar ratio. Note that the first baking is performed in an inert atmosphere, an oxidation atmosphere, or a reduced-pressure atmosphere at a temperature higher than or equal to 400° C. and lower than or equal to 1700° C., preferably higher than or equal to 900° C. and lower than or equal to 1500° C. The first baking is performed for longer than or equal to 3 minutes and shorter than or equal to 24 hours, preferably longer than or equal to 30 minutes and shorter than or equal to 17 hours, further preferably longer than or equal to 30 minutes and shorter than or equal to 5 hours, for example. When the first baking is performed under the above conditions, secondary reactions other than a reaction for producing an In—Zn oxide can be suppressed, and the impurity concentration in the In—Zn oxide can be reduced. Thus, the In—Zn oxide can be crystallized, and the crystallinity of the In—Zn oxide can be increased.

The first baking may be performed plural times at different temperatures and/or in different atmospheres. For example, the In—Zn oxide may be held at a first temperature in a first atmosphere and then at a second temperature in a second atmosphere. Specifically, it is preferable that the first atmosphere be an inert atmosphere or a reduced-pressure atmosphere and the second atmosphere be an oxidation atmosphere. This is because oxygen vacancies are, in some cases, generated in the In—Zn oxide when impurities contained in the In—Zn oxide are reduced in the first atmosphere. Therefore, it is preferable that oxygen vacancies in the obtained In—Zn oxide be reduced in the second atmosphere. The impurity concentration and oxygen vacancies in the In—Zn oxide are reduced, whereby the crystallinity of the In—Zn oxide can be increased.

Next, the In—Zn oxide powder is obtained by pulverizing the In—Zn oxide in a step S103.

The In—Zn oxide has a high proportion of crystals with surface structures of planes parallel to the a-b plane. Therefore, the obtained In—Zn oxide powder includes many flat plate-like crystal grains whose top and bottom surfaces are parallel to the a-b plane. Moreover, the crystal of the In—Zn oxide is in many cases a hexagonal crystal; therefore, in many cases, the above flat plate-like crystal grains each have the shape of a hexagonal cylinder whose top and bottom surfaces are approximately equilateral hexagons each having internal angles of 120°.

Next, the grain size of the obtained In—Zn oxide powder is checked in a step S104. Here, the average grain size of the In—Zn oxide powder is checked to be less than or equal to 3 μm, preferably less than or equal to 2 μm, further preferably less than or equal to 1 μm. Note that the step S104 may be omitted and only the In—Zn oxide powder whose grain size is less than or equal to 3 μm, preferably less than or equal to 2 μm, further preferably less than or equal to 1 μm may be sifted using a grain size filter. The average grain size of the In—Zn oxide powder can be certainly less than or equal to 3 μm, preferably less than or equal to 2 μm, further preferably less than or equal to 1 μm by sifting the In—Zn oxide powder to have the grain size which is less than or equal to 3 μm, preferably less than or equal to 2 μm, further preferably less than or equal to 2 μm.

In the case where the average grain size of the In—Zn oxide powder exceeds a predetermined size in the step S104, the procedure returns to the step S103 and the In—Zn oxide powder is ground again.

In the above manner, the In—Zn oxide powder whose average grain size is less than or equal to 3 μm, preferably less than or equal to 2 μm, further preferably less than or equal to 1 μm can be obtained. Note that the average grain size of the obtained In—Zn oxide powder is less than or equal to 3 μm, preferably less than or equal to 2 μm, further preferably less than or equal to 1 μm, which enables the grain size of a crystal grain included in a sputtering target that is to be formed later to be reduced.

Next, FIG. 1B shows formation of a sputtering target with use of the In—Zn oxide powder obtained in the flow chart shown in FIG. 1A.

In a step S111, the In—Zn oxide powder is made to spread over a mold and molded. Here, molding refers to making the In—Zn oxide powder spread over a mold to obtain a uniform thickness. Specifically, the In—Zn oxide powder is introduced to the mold, and then vibration is externally applied so that the In—Zn oxide powder is molded. Alternatively, the In—Zn oxide powder is introduced to the mold, and then molding is performed using a roller or the like so as to obtain a uniform thickness. Note that in the step S111, slurry in which the In—Zn oxide powder is mixed with water, a dispersant, and a binder may be molded. In that case, a filter is spread over the mold, and the slurry is poured into the mold and then molded by sucking the mold from the bottom through a filter. After that, drying treatment is performed on a molded body after the mold is sucked. The drying treatment is preferably natural drying because the molded body is less likely to be cracked. After that, the molded body is subjected to heat treatment at a temperature higher than or equal to 300° C. and lower than or equal to 700° C., so that residual moisture or the like which cannot be taken out by natural drying is removed. Note that as the filter, a filter in which a porous resin film is attached over a woven fabric or a felt may be used.

When the In—Zn oxide powder including many flat-plate-like crystal grains whose top and bottom surfaces are parallel to the a-b plane is made to spread over the mold and molded, the crystal grains are arranged with the planes which are parallel to the a-b plane thereof facing upward. Therefore, the proportion of the surface structures of planes parallel to the a-b plane can be increased in such a manner that the obtained In—Zn oxide powder is made to spread over the mold and molded. Note that the mold may be formed of a metal or an oxide and the upper shape thereof is rectangular or rounded.

Next, first pressure treatment is performed on the In—Zn oxide powder in a step S112. Then, second baking is performed in a step S113 to obtain a plate-like In—Zn oxide. The second baking is performed under conditions similar to those of the first baking. The crystallinity of the In—Zn oxide can be increased by performing the second baking.

Note that the first pressure treatment may be performed in any manner as long as the In—Zn oxide powder can be pressed. For example, a weight which is formed of the same kind of material as the mold can be used. Alternatively, the In—Zn oxide powder may be pressed under high pressure using compressed air. Besides, the first pressure treatment can be performed using a known technique. Note that the first pressure treatment may be performed at the same time as the second baking.

Planarization treatment may be performed after the first pressure treatment. As the planarization treatment, chemical mechanical polishing (CMP) treatment or the like can be employed.

The plate-like In—Zn oxide thus obtained becomes a polycrystalline In—Zn oxide with high crystallinity.

Next, the thickness of the obtained plate-like In—Zn oxide is checked in a step S114. When the thickness of the plate-like In—Zn oxide is less than a desired thickness, the procedure returns to the step S111 and the In—Zn oxide powder is made to spread over the plate-like In—Zn oxide and molded. When the plate-like In—Zn oxide has a desired thickness in the step S 114, the plate-like In—Zn oxide is used as a sputtering target. The description of steps following the step S111 when the thickness of the plate-like In—Zn oxide is less than a desired thickness is given below.

Next, in the step S112, second pressure treatment is performed on the plate-like In—Zn oxide and the In—Zn oxide powder over the plate-like In—Zn oxide. Then, in the step S113, third baking is performed, whereby a plate-like In—Zn oxide whose thickness is increased by the thickness of the In—Zn oxide powder is obtained. A plate-like In—Zn oxide with an increased thickness is obtained through crystal growth with use of the plate-like In—Zn oxide as a seed crystal; therefore, the plate-like In—Zn oxide is a polycrystalline In—Zn oxide with high crystallinity.

Note that the third baking may be performed under conditions similar to those of the second baking. The second pressure treatment may be performed under conditions similar to those of the first pressure treatment. Note that the second pressure treatment may be performed at the same time as the third baking.

The thickness of the obtained plate-like In—Zn oxide is checked again in the step S114.

Through the above steps, the thickness of the plate-like In—Zn oxide can be gradually increased while the crystal alignment is improved.

By repeating these steps of increasing the thickness of a plate-like In—Zn oxide n (n is a natural number) times, the plate-like In—Zn oxide having a desired thickness (t), for example, greater than or equal to 2 mm and less than or equal to 20 mm, preferably greater than or equal to 3 mm and less than or equal to 20 mm can be obtained. The plate-like In—Zn oxide is used as a sputtering target.

After that, planarization treatment may be performed.

Note that fourth baking may be performed on the obtained sputtering target. The fourth baking is performed under conditions similar to those of the first baking. A sputtering target including a polycrystalline In—Zn oxide with much higher crystallinity can be obtained by performing the fourth baking.

In the above manner, the sputtering target which includes a polycrystalline In—Zn oxide containing a plurality of crystal grains having cleavage planes parallel to the a-b plane and a small average grain size can be formed.

Note that the sputtering target formed in such a manner can have high density. When the density of the sputtering target is increased, the density of a film to be deposited can also be increased. Specifically, the relative density of the sputtering target can be set to be higher than or equal to 90%, higher than or equal to 95%, or higher than or equal to 99%.

This embodiment can be implemented in appropriate combination with any of the other embodiments and example.

### Embodiment 2

In this embodiment, a method for using a sputtering target including a polycrystalline In—Zn oxide will be described.

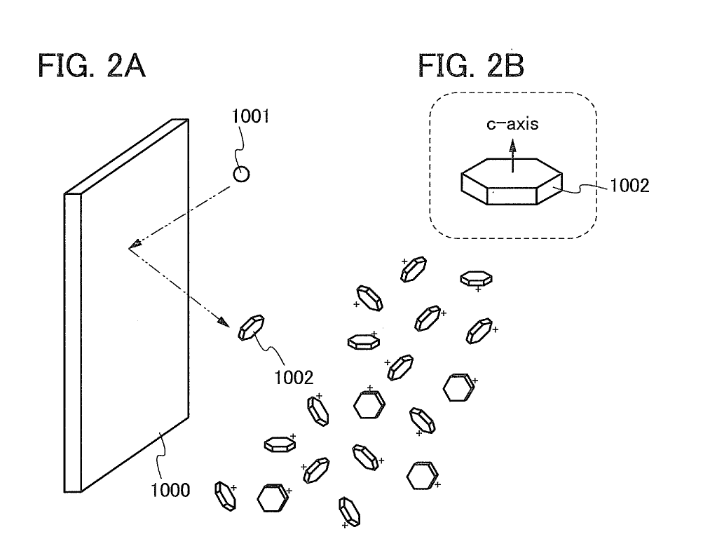

FIG. 2A is a schematic view illustrating a situation in which an ion 1001 collides with a sputtering target 1000, whereby a sputtered particle 1002 is separated. Note that the sputtered particle 1002 may have a hexagonal cylinder shape whose hexagonal plane is parallel to an a-b plane. In such a case, a direction perpendicular to the hexagonal plane is a c-axis direction (see FIG. 2B). The diameter of a plane of the sputtered particle 1002, which is parallel to the a-b plane, is about greater than or equal to 1 nm and less than or equal to 30 nm. As the ion 1001, an oxygen cation is used. Further, in addition to the oxygen cation, an argon cation may be used. Instead of the argon cation, a cation of another rare gas may be used. Here, the term “equivalent circle diameter on a plane” refers to the diameter of a perfect circle having the same area as the plane.

With use of the oxygen cation as the ion 1001, plasma damage at the film formation can be alleviated. Thus, when the ion 1001 collides with the surface of the sputtering target 1000, a lowering in crystallinity of the sputtering target 1000 can be suppressed or a change of the sputtering target 1000 into an amorphous state can be suppressed.

It is preferable that the sputtered particle 1002 which is separated be positively charged. There is no particular limitation on a timing of when the sputtered particle 1002 is positively charged, but it is preferable that the sputtered particle 1002 be positively charged by receiving an electric charge when the ion 1001 collides. Alternatively, in the case where plasma is generated, it is preferable that the sputtered particle 1002 be positively charged by being exposed to plasma. Further alternatively, it is preferable that the ion 1001 which is an oxygen cation be bonded to a side surface, a top surface, or a bottom surface of the sputtered particle 1002, whereby the sputtered particle 1002 is positively charged.

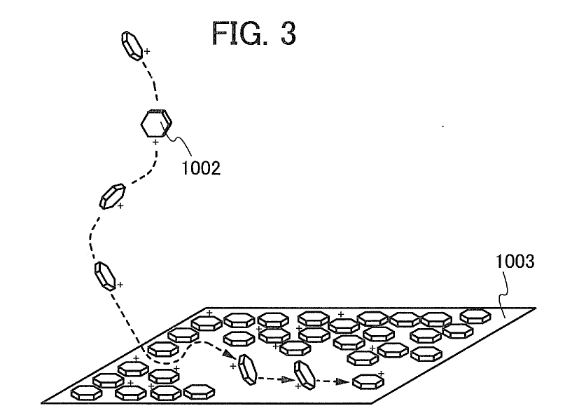

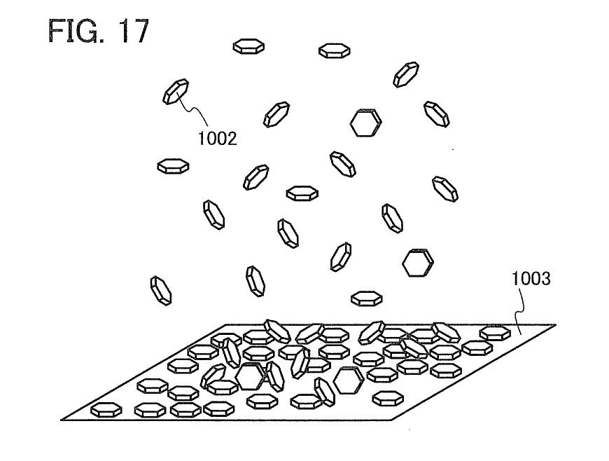

Below is described a situation where sputtered particles are moved to a deposition surface and deposited, with reference to FIG. 3 and FIG. 17. Note that FIG. 17 illustrates a case where the sputtered particles are not charged, and FIG. 3 illustrates a case where the sputtered particles are positively charged.

As illustrated in FIG. 17, in the case where the sputtered particles 1002 are not charged, the sputtered particles 1002 fall irregularly to a deposition surface 1003. Thus, the sputtered particles 1002 are deposited randomly also in a region where other sputtered particles 1002 have been already deposited. Accordingly, an In—Zn oxide film which is obtained by deposition has neither a uniform thickness nor a uniform crystal alignment.

Note that the deposition surface 1003 preferably has an insulating property. When the deposition surface 1003 is an insulating surface, the sputtered particles 1002 which are deposited on the deposition surface 1003 are unlikely to loose positive charges. However, in the case where the deposition rate of the sputtered particles 1002 is lower than the rate at which a positive charge is lost, the deposition surface 1003 may have conductivity.

As illustrated in FIG. 3, in the case where the sputtered particles 1002 are positively charged, the sputtered particles 1002 are deposited in a region of the deposition surface 1003, where no sputtered particle 1002 has been deposited yet. This is because the sputtered particles 1002 which are positively charged repel with each other. Further, c-axes of crystal parts of the sputtered particles 1002 deposited in the above manner are aligned in a direction perpendicular to the deposition surface 1003; accordingly, a CAAC-OS film is formed. Thus, an In—Zn oxide film obtained by deposition has a uniform thickness and a uniform crystal alignment. As described above, the sputtered particles are not deposited randomly. The sputtered particles which are positively charged interact with each other and are deposited orderly so that c-axes are aligned in a direction perpendicular to the deposition surface.

When the sputtering target is used with the above method, an In—Zn oxide film with a uniform thickness and a uniform crystal alignment can be formed.

This embodiment can be implemented in appropriate combination with any of the other embodiments and example.

### Embodiment 3

In this embodiment, a film formation apparatus with which the In—Zn oxide film with a high degree of crystallinity described in Embodiment 2 is formed will be described.

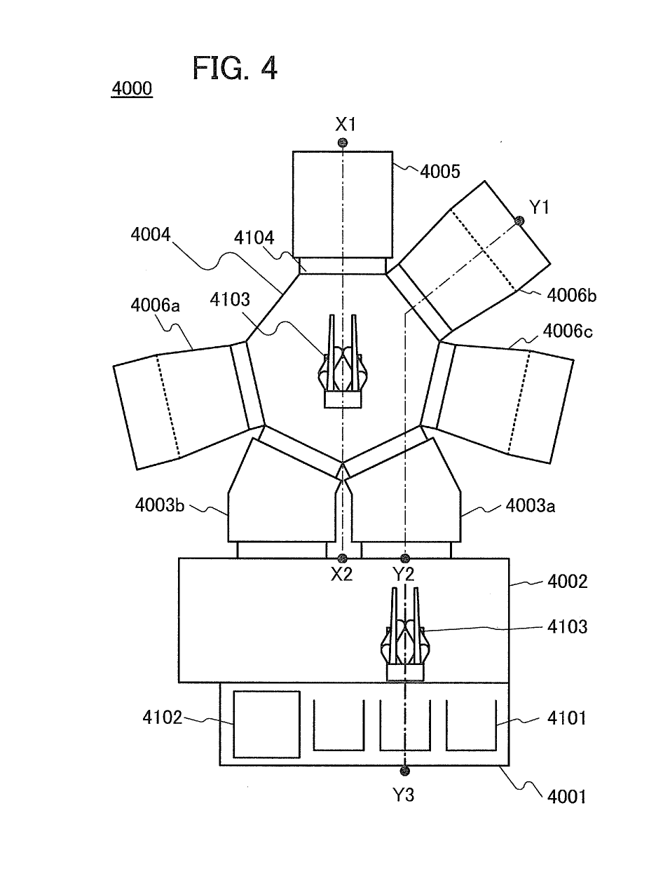

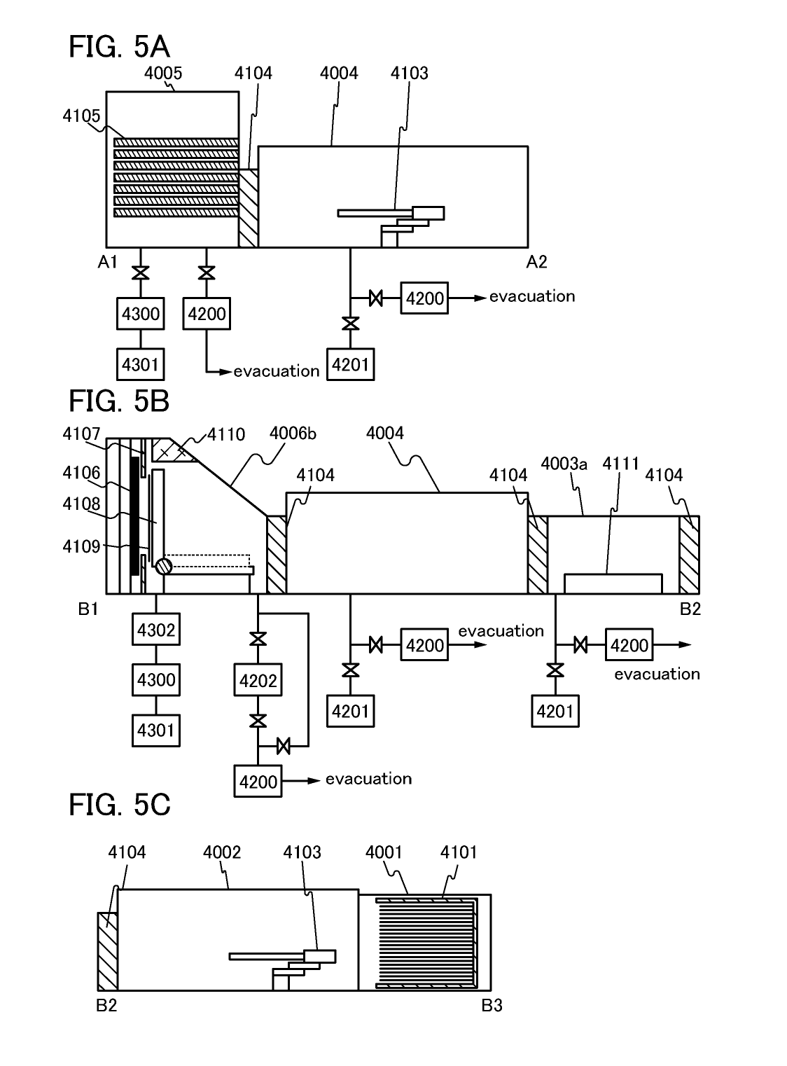

First, a structure of a film formation apparatus which allows the entry of few impurities into a film during film formation is described with reference to FIG. 4 and FIGS. 5A to 5C.

FIG. 4 is a top view schematically illustrating a single wafer multi-chamber film formation apparatus 4000. The film formation apparatus 4000 includes an atmosphere-side substrate supply chamber 4001 including a cassette port 4101 for holding a substrate and an alignment port 4102 for performing alignment of a substrate, an atmosphere-side substrate transfer chamber 4002 through which a substrate is transferred from the atmosphere-side substrate supply chamber 4001, a load lock chamber 4003a where a substrate is carried and the pressure is switched from atmospheric pressure to reduced pressure or from reduced pressure to atmospheric pressure, an unload lock chamber 4003b where a substrate is carried out and the pressure is switched from reduced pressure to atmospheric pressure or from atmospheric pressure to reduced pressure, a transfer chamber 4004 through which a substrate is transferred in a vacuum, a substrate heating chamber 4005 where a substrate is heated, and film formation chambers 4006a, 4006b, and 4006c in each of which a target is placed for film formation.

Note that a plurality of the cassette ports 4101 may be provided as illustrated in FIG. 4 (in FIG. 4, three cassette ports 4101 are provided).

The atmosphere-side substrate transfer chamber 4002 is connected to the load lock chamber 4003a and the unload lock chamber 4003b, the load lock chamber 4003a and the unload lock chamber 4003b are connected to the transfer chamber 4004, and the transfer chamber 4004 is connected to the substrate heating chamber 4005 and the film formation chambers 4006a, 4006b, and 4006c.

Gate valves 4104 are provided for connecting portions between chambers so that each chamber except the atmosphere-side substrate supply chamber 4001 and the atmosphere-side substrate transfer chamber 4002 can be independently kept under vacuum. Moreover, the atmosphere-side substrate transfer chamber 4002 and the transfer chamber 4004 each include a transfer robot 4103, with which a glass substrate can be transferred.

Further, it is preferable that the substrate heating chamber 4005 also serve as a plasma treatment chamber. The film formation apparatus 4000 enables a substrate to transfer without being exposed to the air between treatment and treatment; therefore, adsorption of impurities on the substrate can be suppressed. In addition, the order of film formation, heat treatment, or the like can be freely determined. Note that the number of the transfer chambers, the number of the film formation chambers, the number of the load lock chambers, the number of the unload lock chambers, and the number of the substrate heating chambers are not limited to the above, and the numbers thereof can be set as appropriate depending on the space for placement or the process conditions.

Next, FIG. 5A, FIG. 5B, and FIG. 5C are a cross-sectional view taken along dashed-dotted line X1-X2, a cross-sectional view taken along dashed-dotted line Y1-Y2, and a cross-sectional view taken along dashed-dotted line Y2-Y3, respectively, in the film formation apparatus 4000 illustrated in FIG. 4.

FIG. 5A is a cross section of the substrate heating chamber 4005 and the transfer chamber 4004, and the substrate heating chamber 4005 includes a plurality of heating stages 4105 which can hold a substrate. Note that although the substrate heating chamber 4005 including the seven heating stages 4105 is illustrated in FIG. 5A, one embodiment of the present invention is not limited to such a structure. The number of heating stages 4105 may be greater than or equal to one and less than seven. Alternatively, the number of heating stages 4105 may be greater than or equal to eight. It is preferable to increase the number of the heating stages 4105 because a plurality of substrates can be subjected to heat treatment at the same time, which leads to an increase in productivity. Further, the substrate heating chamber 4005 is connected to a vacuum pump 4200 through a valve. As the vacuum pump 4200, a dry pump and a mechanical booster pump can be used, for example.

As heating mechanism which can be used for the substrate heating chamber 4005, a resistance heater or the like may be used for heating, for example. Alternatively, heat conduction or heat radiation from a medium such as a heated gas may be used as the heating mechanism. For example, rapid thermal anneal (RTA) treatment, such as gas rapid thermal anneal (GRTA) treatment or lamp rapid thermal anneal (LRTA) treatment, can be used. The LRTA treatment is treatment for heating an object by radiation of light (an electromagnetic wave) emitted from a lamp, such as a halogen lamp, a metal halide lamp, a xenon arc lamp, a carbon arc lamp, a high-pressure sodium lamp, or a high-pressure mercury lamp. A GRTA apparatus is an apparatus for performing heat treatment using a high-temperature gas. An inert gas is used as a gas.

Moreover, the substrate heating chamber 4005 is connected to a refiner 4301 through a mass flow controller 4300. Note that although the refiner 4301 and the mass flow controller 4300 can be provided for each of a plurality of kinds of gases, only one refiner 4301 and one mass flow controller 4300 are provided for easy understanding.

As the gas introduced to the substrate heating chamber 4005, a gas whose dew point is −80° C. or lower, preferably −100° C. or lower can be used; for example, an oxygen gas, a nitrogen gas, and a rare gas (e.g., an argon gas) are used.

The transfer chamber 4004 includes the transfer robot 4103. The transfer robot 4103 includes a plurality of movable portions and an arm for holding a substrate and can transfer a substrate to each chamber. Further, the transfer chamber 4004 is connected to a vacuum pump 4200 and a cryopump 4201 through valves. With such a structure, evacuation can be performed using the vacuum pump 4200 when the pressure inside the transfer chamber 4004 is in the range of atmospheric pressure to low vacuum (approximately 0.1 Pa to several hundred Pa) and then, by switching the valves, evacuation can be performed using the cryopump 4201 when the pressure inside the transfer chamber 4004 is in the range of middle vacuum to ultra-high vacuum (0.1 Pa to 1×10⁻⁷ Pa).

Alternatively, two or more cryopumps 4201 may be connected in parallel to the transfer chamber 4004. With such a structure, even when one of the cryopumps is in regeneration, evacuation can be performed using any of the other cryopumps. Note that the above regeneration refers to treatment for discharging molecules (or atoms) entrapped in the cryopump. When molecules (or atoms) are entrapped too much in a cryopump, the evacuation capability of the cryopump is lowered; therefore, regeneration is performed regularly.

FIG. 5B is a cross section of the film formation chamber 4006b, the transfer chamber 4004, and the load lock chamber 4003a.

Here, the details of the film formation chamber (sputtering chamber) are described with reference to FIG. 5B. The film formation chamber 4006b illustrated in FIG. 5B includes a target 4106, an attachment protection plate 4107, and a substrate stage 4108. Note that here, a substrate 4109 is provided on the substrate stage 4108. Although not illustrated, the substrate stage 4108 may include a substrate holding mechanism which holds the substrate 4109, a rear heater which heats the substrate 4109 from the back surface, or the like.

Note that the substrate stage 4108 is held substantially vertically to a floor during film formation and is held substantially parallel to the floor when the substrate is delivered. In FIG. 5B, the position where the substrate stage 4108 is held when the substrate is delivered is denoted by a dashed line. With such a structure, the probability that dust or a particle which might be mixed into the film formation is attached to the substrate 4109 can be lowered as compared to the case where the substrate stage 4108 is held parallel to the floor. However, there is a possibility that the substrate 4109 falls when the substrate stage 4108 is held vertically (90°) to the floor; therefore, the angle of the substrate stage 4108 to the floor is preferred to be greater than or equal to 80° and lower than 90°.

The attachment protection plate 4107 can suppress deposition of a particle which is sputtered from the target 4106 on a region where deposition is not needed. Moreover, the attachment protection plate 4107 is preferably processed to prevent accumulated sputtered particles from being separated. For example, blasting treatment which increases surface roughness may be performed, or roughness may be formed on the surface of the attachment protection plate 4107.

The film formation chamber 4006b is connected to a mass flow controller 4300 through a gas heating system 4302, and the gas heating system 4302 is connected to a refiner 4301 through the mass flow controller 4300. With the gas heating system 4302, a gas to be introduced to the film formation chamber 4006b can be heated to a temperature higher than or equal to 40° C. and lower than or equal to 400° C., preferably higher than or equal to 50° C. and lower than or equal to 200° C. Note that although the gas heating system 4302, the mass flow controller 4300, and the refiner 4301 can be provided for each of a plurality of kinds of gases, only one gas heating system 4302, one mass flow controller 4300, and one refiner 4301 are provided for easy understanding. As the gas introduced to the film formation chamber 4006b, a gas whose dew point is −80° C. or lower, preferably −100° C. or lower can be used; for example, an oxygen gas, a nitrogen gas, and a rare gas (e.g., an argon gas) are used.

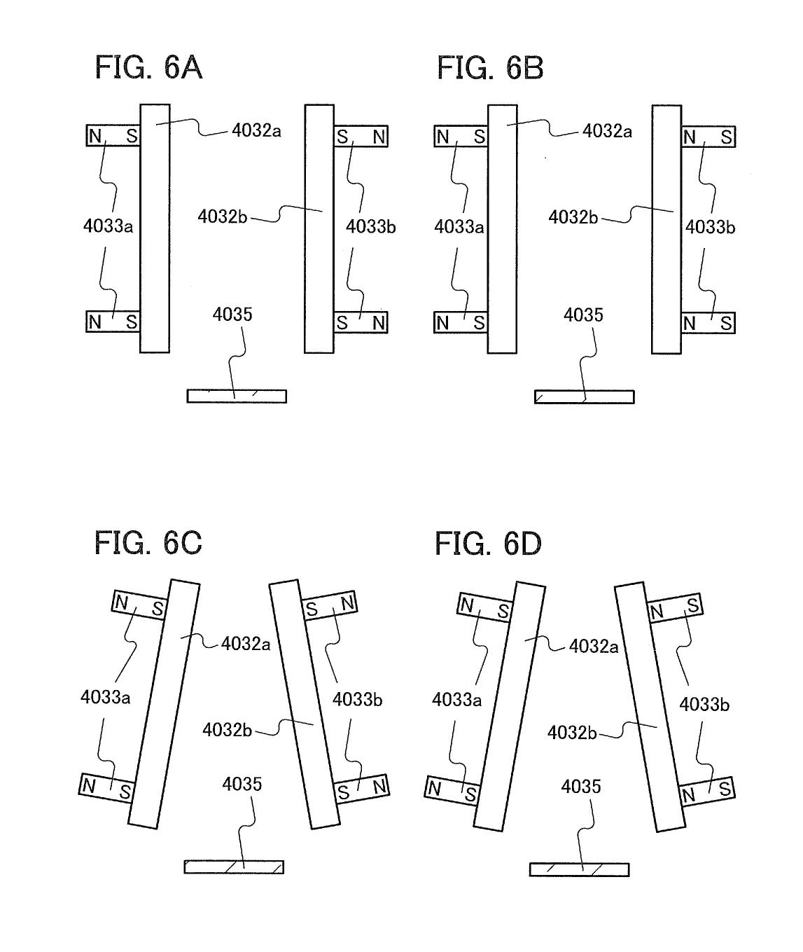

In the film formation chamber 4006b, a facing-target-type sputtering device may be employed. A specific positional relation between sputtering targets, magnets, and a substrate holder is described with reference to FIGS. 6A to 6D.

Each of structures illustrated in FIGS. 6A to 6D includes a first sputtering target 4032a, a second sputtering target 4032b, first cathode magnets 4033a, second cathode magnets 4033b, and a substrate holder 4035. Thus, FIGS. 6A to 6D differ only in positions of the above components

In the structure illustrated in FIG. 6A, the first sputtering target 4032a and the second sputtering target 4032b are provided parallel to face each other. The first cathode magnets 4033a and the second cathode magnets 4033b are provided so that the same polarities face each other. Note that although the first cathode magnet 4033a and the second cathode magnet 4033b are provided so that the S-poles thereof face each other, they may be provided so that the N-poles thereof face each other. The substrate holder 4035 is provided on a lower side of a region where the first sputtering target 4032a and the second sputtering target 4032b face each other; however, the substrate holder 4035 may be provided on an upper side thereof. Alternatively, the substrate holder 4035 may be provided on the upper side and the lower side thereof. When the substrate holder 4035 is provided on the upper side and the lower side, the productivity of the oxide film can be improved. Note that although the substrate holder 4035 is provided so that the top surface thereof is perpendicular to the top surfaces of the first sputtering target 4032a and the second sputtering target 4032b, the substrate holder 4035 may be inclined. With the positional relation illustrated in FIG. 6A, the deposition rate can be increased.

In the structure illustrated in FIG. 6B, the first sputtering target 4032a and the second sputtering target 4032b are provided parallel to face each other. The first cathode magnet 4033a and the second cathode magnet 4033b are provided so that different polarities face each other. The substrate holder 4035 is provided on a lower side of a region where the first sputtering target 4032a and the second sputtering target 4032b face each other; however, the substrate holder 4035 may be provided on an upper side thereof. Alternatively, the substrate holder 4035 may be provided on the upper side and the lower side thereof. When the substrate holder 4035 is provided on the upper side and the lower side, the productivity of the oxide film can be improved. Note that although the substrate holder 4035 is provided so that the top surface thereof is perpendicular to the top surfaces of the first sputtering target 4032a and the second sputtering target 4032b, the substrate holder 4035 may be inclined. With the positional relation illustrated in FIG. 6B, the deposition rate can be increased.

In the structure illustrated in FIG. 6C, the first sputtering target 4032a and the second sputtering target 4032b are provided to face each other with symmetrical inclination (in an inverted V shape). The first cathode magnet 4033a and the second cathode magnet 4033b are provided so that the same polarities face each other. Note that although the first cathode magnet 4033a and the second cathode magnet 4033b are provided so that the S-poles thereof face each other, they may be provided so that the N-poles thereof face each other. The substrate holder 4035 is provided on a lower side of a region where the first sputtering target 4032a and the second sputtering target 4032b face each other (the side on which a distance between the targets is larger). With the positional relation illustrated in FIG. 6C, the deposition rate can be increased because sputtered particles efficiently fall to the substrate holder 4035.

In the structure illustrated in FIG. 6D, the first sputtering target 4032a and the second sputtering target 4032b are provided to face each other with symmetrical inclination (in an inverted V shape). The first cathode magnet 4033a and the second cathode magnet 4033b are provided so that different polarities face each other. The substrate holder 4035 is provided on a lower side of a region where the first sputtering target 4032a and the second sputtering target 4032b face each other (the side on which a distance between the targets is larger). With the positional relation illustrated in FIG. 6D, the deposition rate can be increased because sputtered particles efficiently fall to the substrate holder 4035.

In each of the above-described structures of the facing-target-type sputtering device, plasma is confined between the targets; therefore, plasma damage to a substrate can be reduced. Further, step coverage can be improved because an incident angle of a sputtered particle to the substrate can be made smaller depending on the inclination of the target.

Note that a parallel-plate-type sputtering device or an ion beam sputtering device may be provided in the film formation chamber 4006b.

In the case where the refiner is provided just before the gas is introduced, the length of a pipe between the refiner and the film formation chamber 4006b is less than or equal to 10 m, preferably less than or equal to 5 m, further preferably less than or equal to 1 m. When the length of the pipe is less than or equal to 10 m, less than or equal to 5 m, or less than or equal to 1 m, the effect of the release of gas from the pipe can be reduced accordingly. As the pipe of the gas, a metal pipe the inside of which is covered with an iron fluoride, an aluminum oxide, a chromium oxide, or the like may be used. With the above pipe, the amount of released gas containing impurities is made small and the entry of impurities into the gas can be reduced as compared with a SUS316L-EP pipe, for example. Further, a high-performance ultra-compact metal gasket joint (a UPG joint) is preferably used as a joint of the pipe. A structure where all the materials of the pipe are metals is preferable because the effect of the generated released gas or the external leakage can be reduced compared with a structure where resin or the like is used.

The film formation chamber 4006b is connected to a turbo molecular pump 4202 and a vacuum pump 4200 through valves.

In addition, the film formation chamber 4006b is provided with a cryotrap 4110.

The cryotrap 4110 is a mechanism which can adsorb a molecule (or an atom) having a relatively high melting point, such as water. The turbo molecular pump 4202 is capable of stably evacuating a large-sized molecule (or atom), needs low frequency of maintenance, and thus enables high productivity, whereas it has a low capability in evacuating hydrogen and water. Hence, the cryotrap 4110 is connected to the film formation chamber 4006b so as to have a high capability in evacuating water or the like. The temperature of a refrigerator of the cryotrap 4110 is set to be lower than or equal to 100 K, preferably lower than or equal to 80 K. In the case where the cryotrap 4110 includes a plurality of refrigerators, it is preferable to set the temperature of each refrigerator at a different temperature because efficient evacuation is possible. For example, the temperatures of a first-stage refrigerator and a second-stage refrigerator may be set at 100 K or lower and 20 K or lower, respectively.

Note that the evacuation method of the film formation chamber 4006b is not limited to the above, and a structure similar to that in the evacuation method described in the transfer chamber 4004 (the evacuation method using the cryopump and the vacuum pump) may be employed. Needless to say, the evacuation method of the transfer chamber 4004 may have a structure similar to that of the film formation chamber 4006b (the evacuation method using the turbo molecular pump and the vacuum pump).

Note that in each of the above transfer chamber 4004, the substrate heating chamber 4005, and the film formation chamber 4006b, the back pressure (total pressure) and the partial pressure of each gas molecule (atom) are preferably set as follows. In particular, the back pressure and the partial pressure of each gas molecule (atom) in the film formation chamber 4006b need to be noted because impurities might enter a film to be formed.

In each of the above chambers, the back pressure (total pressure) is less than or equal to 1×10⁻⁴ Pa, preferably less than or equal to 3×10⁻⁵ Pa, further preferably less than or equal to 1×10⁻⁵ Pa. In each of the above chambers, the partial pressure of a gas molecule (atom) having a mass-to-charge ratio (m/z) of 18 is less than or equal to 3×10⁻⁵ Pa, preferably less than or equal to 1×10⁻⁵ Pa, further preferably less than or equal to 3×10⁻⁶ Pa. Further, in each of the above chambers, the partial pressure of a gas molecule (atom) having a mass-to-charge ratio (m/z) of 28 is less than or equal to 3×10⁻⁵ Pa, preferably less than or equal to 1×10⁻⁵ Pa, further preferably less than or equal to 3×10⁻⁶ Pa. Moreover, in each of the above chambers, the partial pressure of a gas molecule (atom) having a mass-to-charge ratio (m/z) of 44 is less than or equal to 3×10⁻⁵ Pa, preferably less than or equal to 1×10⁻⁵ Pa, further preferably less than or equal to 3×10⁻⁶ Pa.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc. can be used.

Moreover, the above transfer chamber 4004, the substrate heating chamber 4005, and the film formation chamber 4006b preferably have a small amount of external leakage or internal leakage.

For example, in each of the above transfer chamber 4004, the substrate heating chamber 4005, and the film formation chamber 4006b, the leakage rate is less than or equal to 3×10⁻⁶ Pa·m³/s, preferably less than or equal to 1×10⁻⁶ Pa·m³/s. The leakage rate of a gas molecule (atom) having a mass-to-charge ratio (m/z) of 18 is less than or equal to 1×10⁻⁷ Pa·m³/s, preferably less than or equal to 3×10⁻⁸ Pa·m³/s. The leakage rate of a gas molecule (atom) having a mass-to-charge ratio (m/z) of 28 is less than or equal to 1×10⁻⁵ Pa·m³/s, preferably less than or equal to 1×10⁻⁶ Pa·m³/s. The leakage rate of a gas molecule (atom) having a mass-to-charge ratio (m/z) of 44 is less than or equal to 3×10⁻⁶ Pa·m³/s, preferably less than or equal to 1×10⁻⁶ Pa·m³/s.

Note that a leakage rate can be derived from the total pressure and partial pressure measured using the mass analyzer.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or due to gas released from an internal member. Measures need to be taken from both aspects of external leakage and internal leakage in order that the leakage rate be lower than or equal to the above value.

For example, an open/close portion of the film formation chamber 4006b can be sealed with a metal gasket. For the metal gasket, metal covered with an iron fluoride, an aluminum oxide, or a chromium oxide is preferably used. The metal gasket enables higher adhesion than an O-ring, and can reduce the external leakage. Further, with use of the metal covered with an iron fluoride, an aluminum oxide, a chromium oxide, or the like which is in the passive state, the release of gas containing impurities released from the metal gasket is suppressed, so that the internal leakage can be reduced.

For a member of the film formation apparatus 4000, a material such as aluminum, chromium, titanium, zirconium, nickel, or vanadium, which releases a smaller amount of gas containing impurities, is used. Alternatively, for the above member, an alloy containing iron, chromium, nickel, and the like covered with the above material may be used. The alloy containing iron, chromium, nickel, and the like is rigid, resistant to heat, and suitable for processing. Here, when surface unevenness of the member is decreased by polishing or the like to reduce the surface area, the released gas can be reduced.

Alternatively, the above member of the film formation apparatus 4000 may be covered with an iron fluoride, an aluminum oxide, a chromium oxide, or the like.

The member of the film formation apparatus 4000 is preferably formed with only metal as much as possible. For example, in the case where a viewing window formed with quartz or the like is provided, it is preferable that the surface of the viewing window be thinly covered with an iron fluoride, an aluminum oxide, a chromium oxide, or the like so as to suppress a release of gas.

When an adsorbate is present in the film formation chamber, the adsorbate does not affect the pressure in the film formation chamber because it is adsorbed onto an inner wall or the like; however, the adsorbate causes gas to be released when the inside of the film formation chamber is evacuated. Therefore, although there is no correlation between the leakage rate and the evacuation rate, it is important that the adsorbate present in the film formation chamber be desorbed as much as possible and evacuation be performed in advance with use of a pump with high evacuation capability. Note that the film formation chamber may be subjected to baking for promotion of desorption of the adsorbate. By the baking, the rate of desorption of the adsorbate can be increased about tenfold. The baking should be performed at a temperature higher than or equal to 100° C. and lower than or equal to 450° C. At this time, when the adsorbate is removed while an inert gas is introduced to the film formation chamber, the desorption rate of water or the like, which is difficult to desorb simply by evacuation, can be further increased. Note that the rate of desorption of the adsorbate can be further increased by heating of the inert gas to be introduced at substantially the same temperature as the temperature of the baking. Here, a rare gas is preferably used as an inert gas. Depending on the kind of a film to be formed, oxygen or the like may be used instead of an inert gas. For example, in the case of forming an In—Zn oxide, using oxygen, which is the main component of the oxide, is preferable in some cases.

Alternatively, treatment for evacuating the inside of the film formation chamber is preferably performed a certain period of time after a heated oxygen gas, a heated inert gas such as a heated rare gas, or the like is introduced to increase pressure in the film formation chamber. The introduction of the heated gas can desorb the adsorbate in the film formation chamber, and the impurities present in the film formation chamber can be reduced. Note that an advantageous effect can be achieved when this treatment is repeated more than or equal to twice and less than or equal to 30 times, preferably more than or equal to 5 times and less than or equal to 15 times. Specifically, an inert gas, oxygen, or the like with a temperature higher than or equal to 40° C. and lower than or equal to 400° C., preferably higher than or equal to 50° C. and lower than or equal to 200° C. is introduced to the film formation chamber, so that the pressure therein can be kept to be greater than or equal to 0.1 Pa and less than or equal to 10 kPa, preferably greater than or equal to 1 Pa and less than or equal to 1 kPa, further preferably greater than or equal to 5 Pa and less than or equal to 100 Pa in the time range of 1 minute to 300 minutes, preferably 5 minutes to 120 minutes. After that, the inside of the film formation chamber is evacuated in the time range of 5 minutes to 300 minutes, preferably 10 minutes to 120 minutes.

The rate of desorption of the adsorbate can be further increased also by dummy film formation. Here, the dummy film formation refers to film formation on a dummy substrate by sputtering or the like, in which a film is formed on the dummy substrate and the inner wall of the film formation chamber so that impurities in the film formation chamber and an adsorbate on the inner wall of the film formation chamber are confined in the film. For a dummy substrate, a substrate which releases a smaller amount of gas is preferably used. By performing dummy film formation, the impurity concentration in a film to be formed can be reduced. Note that the dummy deposition may be performed at the same time as the baking of the film formation chamber.

Next, the details of the transfer chamber 4004 and the load lock chamber 4003a illustrated in FIG. 5B and the atmosphere-side substrate transfer chamber 4002 and the atmosphere-side substrate supply chamber 4001 illustrated in FIG. 5C are described.

Note that FIG. 5C is a cross section of the atmosphere-side substrate transfer chamber 4002 and the atmosphere-side substrate supply chamber 4001.

For the transfer chamber 4004 illustrated in FIG. 5B, the description of the transfer chamber 4004 illustrated in FIG. 5A can be referred to.

The load lock chamber 4003a includes a substrate delivery stage 4111. When a pressure in the load lock chamber 4003a becomes an atmospheric pressure by being increased from a reduced pressure, the substrate delivery stage 4111 receives a substrate from the transfer robot 4103 provided in the atmosphere-side substrate transfer chamber 4002. After that, the load lock chamber 4003a is evacuated into vacuum so that the pressure therein becomes a reduced pressure and then the transfer robot 4103 provided in the transfer chamber 4004 receives the substrate from the substrate delivery stage 4111.

Further, the load lock chamber 4003a is connected to a vacuum pump 4200 and a cryopump 4201 through valves. For a method for connecting evacuation systems such as the vacuum pump 4200 and the cryopump 4201, the description of the method for connecting the transfer chamber 4004 can be referred to, and the description thereof is omitted here. Note that the unload lock chamber 4003b illustrated in FIG. 4 can have a structure similar to that in the load lock chamber 4003a.

The atmosphere-side substrate transfer chamber 4002 includes the transfer robot 4103. The transfer robot 4103 can deliver a substrate from the cassette port 4101 to the load lock chamber 4003a or deliver a substrate from the load lock chamber 4003a to the cassette port 4101. Further, a mechanism for cleaning dust or a particle, such as high efficiency particulate air (HEPA) filter, may be provided above the atmosphere-side substrate transfer chamber 4002 and the atmosphere-side substrate supply chamber 4001.

The atmosphere-side substrate supply chamber 4001 includes a plurality of the cassette ports 4101. The cassette port 4101 can hold a plurality of substrates.

When an In—Zn oxide film is formed with use of the above film formation apparatus, the entry of impurities into the In—Zn oxide film can be suppressed. Further, when a film in contact with the In—Zn oxide film is formed with use of the above film formation apparatus, the entry of impurities into the In—Zn oxide film from the film in contact therewith can be suppressed.

Next, a method for forming a CAAC-OS film with use of the above film formation apparatus is described.

In order to form the In—Zn oxide film, the sputtering target described in Embodiment 1 is used.

The surface temperature of the sputtering target is set to be lower than or equal to 100° C., preferably lower than or equal to 50° C., further preferably about room temperature (typically, 25° C.). In a sputtering device for a large substrate, a sputtering target having a large area is often used. However, it is difficult to form a sputtering target for a large substrate without a juncture. In fact, a plurality of sputtering targets are arranged so that there is as little space as possible therebetween to obtain a large shape; however, a slight space is inevitably generated. When the surface temperature of the sputtering target increases, in some cases, Zn or the like is volatilized from such slight spaces, and the spaces might expand gradually. When the space expands, a metal of a backing plate or a metal used for adhesion might be sputtered and cause an increase in the impurity concentration. Thus, it is preferable that the sputtering target be cooled sufficiently.

Specifically, for the backing plate, a metal having high conductivity and a high heat dissipation property (specifically Cu) is used. The sputtering target can be cooled efficiently by making a sufficient amount of cooling water flow through a water channel which is formed in the backing plate.

The In—Zn oxide film is formed in an oxygen gas atmosphere with a substrate heating temperature higher than or equal to 100° C. and lower than or equal to 600° C., preferably higher than or equal to 150° C. and lower than or equal to 550° C., further preferably higher than or equal to 200° C. and lower than or equal to 500° C. The thickness of the In—Zn oxide film is greater than or equal to 1 nm and less than or equal to 40 nm, preferably greater than or equal to 3 nm and less than or equal to 20 nm. As the substrate heating temperature during the film formation is higher, the impurity concentration in the obtained In—Zn oxide film is lower. Further, migration of sputtered particles on a deposition surface is likely to occur; therefore, the atomic arrangement in the In—Zn oxide film is ordered and the density thereof is increased, so that a CAAC-OS film with a high degree of crystallinity is formed easily. Furthermore, when the film formation is performed in an oxygen gas atmosphere, plasma damage is alleviated and a surplus atom such as a rare gas atom is not contained in the oxide film, whereby a CAAC-OS film with a high degree of crystallinity is formed easily. Note that the film formation may be performed in a mixed atmosphere including an oxygen gas and a rare gas. In that case, the percentage of an oxygen gas is set to be greater than or equal to 30 vol. %, preferably greater than or equal to 50 vol. %, further preferably greater than or equal to 80 vol. %.

Note that in the case where the sputtering target includes Zn, plasma damage is alleviated by the film formation in an oxygen gas atmosphere; thus, an In—Zn oxide film in which Zn is unlikely to be volatilized can be obtained.

The In—Zn oxide film is formed under conditions in which the film formation pressure is less than or equal to 0.8 Pa, preferably less than or equal to 0.4 Pa, and the distance between the sputtering target and a substrate is less than or equal to 100 mm, preferably less than or equal to 40 mm, further preferably less than or equal to 25 mm. When the In—Zn oxide film is formed under such a condition, the frequency of the collision between a sputtered particle and another sputtered particle, a gas molecule, or an ion can be reduced. That is, depending on the film formation pressure, the distance between the sputtering target and the substrate is made shorter than the mean free path of a sputtered particle, a gas molecule, or an ion, so that the entry of impurities into the film can be reduced.

For example, when the pressure is 0.4 Pa and the temperature is 25° C. (the absolute temperature is 298 K), a hydrogen molecule (H₂) has a mean free path of 48.7 mm, a helium atom (He) has a mean free path of 57.9 mm, a water molecule (H₂O) has a mean free path of 31.3 mm, an methane molecule (CH₄) has a mean free path of 13.2 mm, a neon atom (Ne) has a mean free path of 42.3 mm, a nitrogen molecule (N₂) has a mean free path of 23.2 mm, a carbon monoxide molecule (CO) has a mean free path of 16.0 mm, an oxygen molecule (O₂) has a mean free path of 26.4 mm, an argon atom (Ar) has a mean free path of 28.3 mm, a carbon dioxide molecule (CO₂) has a mean free path of 10.9 mm, a krypton atom (Kr) has a mean free path of 13.4 mm, and a xenon atom (Xe) has a mean free path of 9.6 mm. Note that doubling of the pressure halves a mean free path and doubling of the absolute temperature doubles a mean free path.

The mean free path depends on pressure, temperature, and the diameter of a molecule (atom). In the case where pressure and temperature are constant, as the diameter of a molecule (atom) is larger, the mean free path is shorter. Note that the diameters of the molecules (atoms) are as follows: H₂: 0.218 nm; He: 0.200 nm; H₂O: 0.272 nm; CH₄: 0.419 nm; Ne: 0.234 nm; N₂: 0.316 nm; CO: 0.380 nm; O₂: 0.296 nm; Ar: 0.286 nm; CO₂: 0.460 nm; Kr: 0.415 nm; and Xe: 0.491 nm.

Thus, as the diameter of a molecule (atom) is larger, the mean free path is shorter and the degree of crystallinity is lowered due to the large diameter of the molecule (atom) when the molecule (atom) enters the film. For this reason, it can be said that, for example, a molecule (atom) whose diameter is larger than that of Ar is likely to behave as an impurity.

Next, heat treatment is performed. The heat treatment is performed under reduced pressure or in an inert atmosphere or an oxidation atmosphere. By the heat treatment, the impurity concentration in the CAAC-OS film can be reduced.

The heat treatment is preferably performed in a manner such that after heat treatment is performed under reduced pressure or in an inert atmosphere, the atmosphere is switched to an oxidation atmosphere with the temperature maintained and heat treatment is further performed. When the heat treatment is performed under reduced pressure or in an inert atmosphere, the impurity concentration in the CAAC-OS film can be reduced; however, oxygen vacancies are caused at the same time. By the heat treatment in an oxidation atmosphere, the caused oxygen vacancies can be reduced.

When heat treatment is performed on the oxide semiconductor film after the film formation in addition to the substrate heating in the film formation, the impurity concentration in the CAAC-OS film can be significantly reduced.

Specifically, the concentration of hydrogen in the CAAC-OS film, which is measured by secondary ion mass spectrometry (SIMS), can be set to be lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³.

The concentration of nitrogen in the CAAC-OS film, which is measured by SIMS, can be set to be lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

The concentration of carbon in the CAAC-OS film, which is measured by SIMS, can be set to be lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

The amount of each of the following gas molecules (atoms) released from the CAAC-OS film can be less than or equal to 1×10¹⁹/cm³, preferably less than or equal to 1×10¹⁸/cm³ or less, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

A measurement method of the amount of released oxygen atoms, which is to be described later, is referred to for a measurement method of the release amount using TDS analysis.

In the above manner, a CAAC-OS film with a high degree of crystallinity can be formed.

This embodiment can be implemented in appropriate combination with any of the other embodiments and example.

### Embodiment 4

In this embodiment, a transistor according to one embodiment of the present invention will be described.

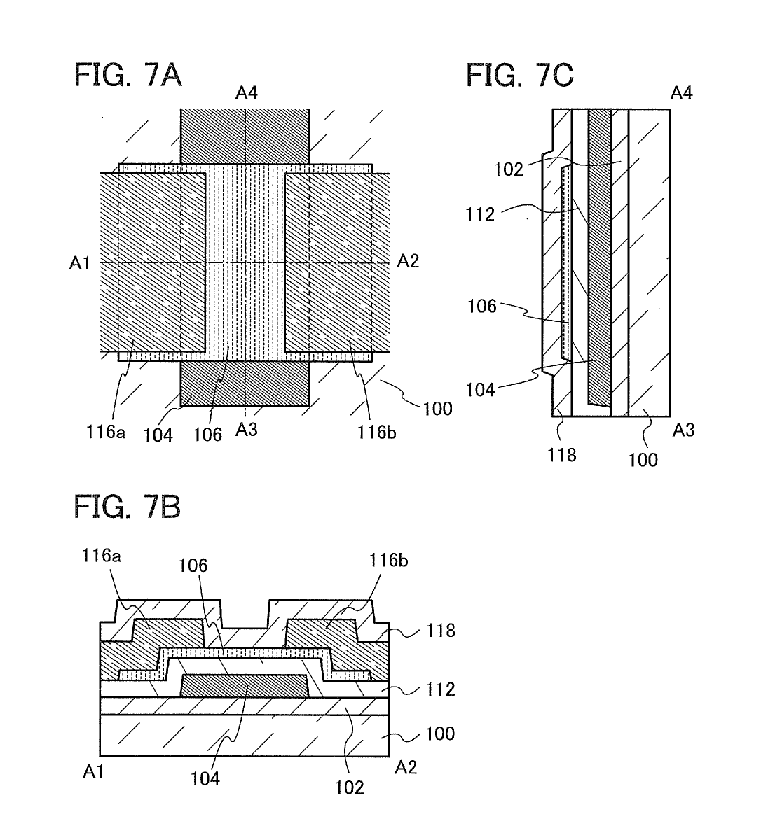

FIG. 7A is a top view of a transistor according to one embodiment of the present invention. FIG. 7B is a cross-sectional view along dashed-dotted line A1-A2 of FIG. 7A. FIG. 7C is a cross-sectional view taken along dashed-dotted line A3-A4 in FIG. 7A. Note that for simplicity, a gate insulating film 112 and the like are not illustrated in FIG. 7A.

FIG. 7B is a cross-sectional view of a transistor including a base insulating film 102 over a substrate 100, a gate electrode 104 over the base insulating film 102, a gate insulating film 112 over the gate electrode 104, an oxide semiconductor film 106 which is over the gate insulating film 112 and overlaps with the gate electrode 104, a source electrode 116a and a drain electrode 116b which are over the oxide semiconductor film 106, and a protective insulating film 118 over the oxide semiconductor film 106, the source electrode 116a, and the drain electrode 116b. Note that FIG. 7B illustrates a structure including the base insulating film 102; however, one embodiment of the present invention is not limited thereto. For example, a structure without the base insulating film 102 may be employed.

Here, the In—Zn oxide film with a high degree of crystallinity which is described in the above embodiment is used as the oxide semiconductor film 106.

The hydrogen concentration in the oxide semiconductor film 106 is set to be lower than or equal to 2×10²⁰ atoms/cm³, preferably lower than or equal to 5×10¹⁹ atoms/cm³, further preferably lower than or equal to 1×10¹⁹ atoms/cm³, sill further preferably, 5×10¹⁸ atoms/cm³. This is because hydrogen included in the oxide semiconductor film 106 sometimes generates unintentional carriers. The generated carriers might be a cause of an increase in the off-state current of the transistor and change in the electrical characteristics of the transistor.

There is no particular limitation on the substrate 100. For example, a glass substrate, a ceramic substrate, a quartz substrate, or a sapphire substrate may be used as the substrate 100. Alternatively, a single crystal semiconductor substrate or a polycrystalline semiconductor substrate made of silicon, silicon carbide, or the like, a compound semiconductor substrate made of silicon germanium or the like, a silicon-on-insulator (SOI) substrate, or the like may be used as the substrate 100. Still alternatively, any of these substrates further provided with a semiconductor element may be used as the substrate 100.

In the case where a large glass substrate such as the 5th generation (1000 mm×1200 mm or 1300 mm×1500 mm), the 6th generation (1500 mm×1800 mm), the 7th generation (1870 mm×2200 mm), the 8th generation (2200 mm×2500 mm), the 9th generation (2400 mm×2800 mm), or the 10th generation (2880 mm×3130 mm) is used as the substrate 100, minute processing is sometimes difficult due to shrinkage of the substrate 100 caused by heat treatment or the like in a manufacturing process of a semiconductor device. Therefore, in the case where the above-described large glass substrate is used as the substrate 100, a substrate which is unlikely to shrink through the heat treatment is preferably used. For example, as the substrate 100, it is possible to use a large glass substrate in which the amount of shrinkage after heat treatment which is performed for an hour at 400° C., preferably 450° C., further preferably 500° C. is less than or equal to 10 ppm, preferably less than or equal to 5 ppm, further preferably less than or equal to 3 ppm.

Further alternatively, a flexible substrate may be used as the substrate 100. Note that as a method for forming a transistor over a flexible substrate, there is also a method in which, after a transistor is formed over a non-flexible substrate, the transistor is separated from the non-flexible substrate and transferred to the substrate 100 which is a flexible substrate. In that case, a separation layer is preferably provided between the non-flexible substrate and the transistor.

The base insulating film 102 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The gate electrode 104 may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances.

The source electrode 116a and the drain electrode 116b may be formed of a single layer or a stacked layer of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances. Note that the source electrode 116a and the drain electrode 116b may have the same composition or different compositions.

Note that a structure in which the source electrode 116a and the drain electrode 116b are in contact with a bottom surface of the oxide semiconductor film 106 may be employed.

The gate insulating film 112 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The protective insulating film 118 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The protective insulating film 118 may be a stacked film including a silicon oxide film and a silicon nitride film. In this case, a silicon oxynitride film may be used instead of the silicon oxide film. As the silicon oxide film, a silicon oxide film with a low defect density is preferably used. Specifically, a silicon oxide film which has a spin density of 3×10¹⁷ spins/cm³ or less, preferably 5×10¹⁶ spins/cm³ or less corresponding to a signal at a g-factor of 2.001 in electron spin resonance (ESR) spectroscopy is used. As the silicon nitride film, a silicon nitride film from which hydrogen and ammonia are less released is used. The amount of released hydrogen and ammonia is preferably measured by thermal desorption spectroscopy (TDS) analysis. Further, a silicon nitride film which oxygen does not penetrates or hardly penetrate is used.

The protective insulating film 118 may be a stacked film including a first silicon oxide film as a first layer, a second silicon oxide film as a second layer, and a silicon nitride film as a third layer. In this case, instead of the first silicon oxide film and/or the second silicon oxide film, a silicon oxynitride film may be used. The first silicon oxide film is preferably a silicon oxide film with a low defect density. Specifically, a silicon oxide film which has a spin density of 3×10¹⁷ spins/cm³ or less, preferably 5×10¹⁶ spins/cm³ or less corresponding to a signal at a g-factor of 2.001 in ESR is used. As the second oxide film, a silicon oxide film containing excess oxygen is used. As the silicon nitride film, a silicon nitride film from which hydrogen and ammonia are less released is used. Further, a silicon nitride film which oxygen does not penetrates or hardly penetrate is used.

The silicon oxide film containing excess oxygen indicates a silicon oxide film from which oxygen can be released by heat treatment or the like. Further, the insulating film containing excess oxygen is an insulating film having a function of releasing oxygen by heat treatment.

] A film from which oxygen is released by heat treatment may release oxygen, the amount of which is greater than or equal to 1×10¹⁸ atoms/cm³, greater than or equal to 1×10¹⁹ atoms/cm³, or greater than or equal to 1×10²⁰ atoms/cm³ in TDS analysis (converted into the number of oxygen atoms).

Here, a method to measure the amount of released oxygen using TDS analysis is described.

The total amount of released gas from a measurement sample in TDS is proportional to the integral value of the ion intensity of the released gas. Then, a comparison with a reference sample is made, whereby the total amount of released gas can be calculated.

For example, the number of released oxygen molecules (N_{O2}) from a measurement sample can be calculated according to Formula (1) using the TDS results of a silicon wafer containing hydrogen at a predetermined density, which is the reference sample, and the TDS results of the measurement sample. Here, all gases having a mass number of 32 which are obtained in the TDS analysis are assumed to originate from an oxygen molecule. CH₃OH, which is given as a gas having a mass number of 32, is not taken into consideration on the assumption that it is unlikely to be present. Further, an oxygen molecule including an oxygen atom having a mass number of 17 or 18 which is an isotope of an oxygen atom is also not taken into consideration because the proportion of such a molecule in the natural world is minimal.

$${N}_{O 2} = \frac{{N}_{H 2}}{{S}_{H 2}} \times {S}_{O 2} \times α \qquad [ Formula 1 ]$$

N_{H2} is the value obtained by conversion of the number of hydrogen molecules desorbed from the standard sample into densities. S_{H2} is the integral value of ion intensity when the standard sample is subjected to TDS analysis. Here, the reference value of the standard sample is set to N_{H2}/S_{H2}. S_{O2} is the integral value of ion intensity when the measurement sample is analyzed by TDS. α is a coefficient affecting the ion intensity in the TDS analysis. Refer to Japanese Published Patent Application No. H6-275697 for details of the Formula 1. Note that the amount of released oxygen was measured with a thermal desorption spectroscopy apparatus produced by ESCO Ltd., EMD-WA1000S/W using a silicon wafer containing hydrogen atoms at 1×10¹⁶ atoms/cm² as the standard sample.

Further, in the TDS analysis, oxygen is partly detected as an oxygen atom. The ratio between oxygen molecules and oxygen atoms can be calculated from the ionization rate of the oxygen molecules. Note that, since the above a includes the ionization rate of the oxygen molecules, the number of the released oxygen atoms can also be estimated through the examination of the number of the released oxygen molecules.

Note that N_{O2} is the number of the released oxygen molecules. The amount of released oxygen when converted into oxygen atoms is twice the number of the released oxygen molecules.

Further, the film from which oxygen is released by heat treatment may contain a peroxide radical. Specifically, the spin density attributed to a peroxide radical is higher than or equal to 5×10¹⁷ spins/cm³. Note that the film containing a peroxide radical may have an asymmetric signal at a g-factor of around 2.01 generated in ESR.

The insulating film containing excess oxygen may be formed using oxygen-excess silicon oxygen (SiOₓ (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

At least one of the gate insulating film 112 and the protective insulating film 118 is preferably an insulating film containing excess oxygen.

In the case where at least one of the gate insulating film 112 and the protective insulating film 118 contains excess oxygen, oxygen vacancies in the oxide semiconductor film 106 can be reduced.

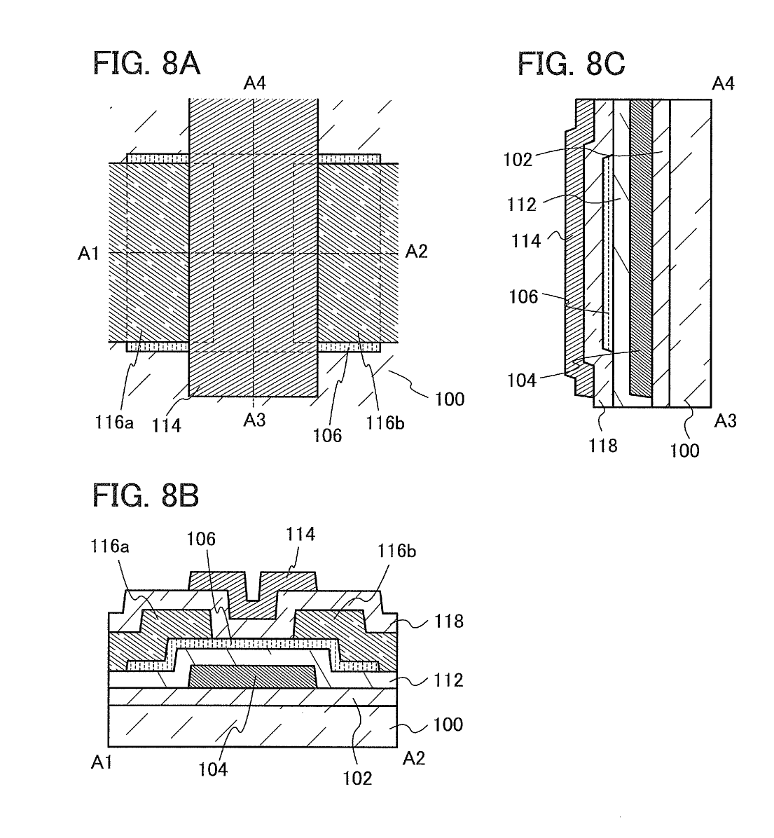

A transistor illustrated in FIGS. 8A to 8C is obtained by additionally providing a back gate electrode 114 in the transistor illustrated in FIGS. 7A to 7C.

FIG. 8A is a top view of a transistor according to one embodiment of the present invention. FIG. 8B is a cross-sectional view taken along dashed-dotted line A1-A2 in FIG. 8A. FIG. 8C is a cross-sectional view along dashed-dotted line A3-A4 of FIG. 8A. Note that for simplicity, the gate insulating film 112 and the like are not illustrated in FIG. 8A.

The threshold voltage of the transistor illustrated in FIGS. 8A to 8C can be controlled easily owing to the back gate electrode 114. Moreover, the on-state current of the transistor can be increased by electrically connecting the back gate electrode 114 to the gate electrode 104. Alternatively, the off-state current of the transistor can be reduced by setting the potential of the back gate electrode 114 to a negative potential (a potential which is lower than that of the source of the transistor) or the source potential.

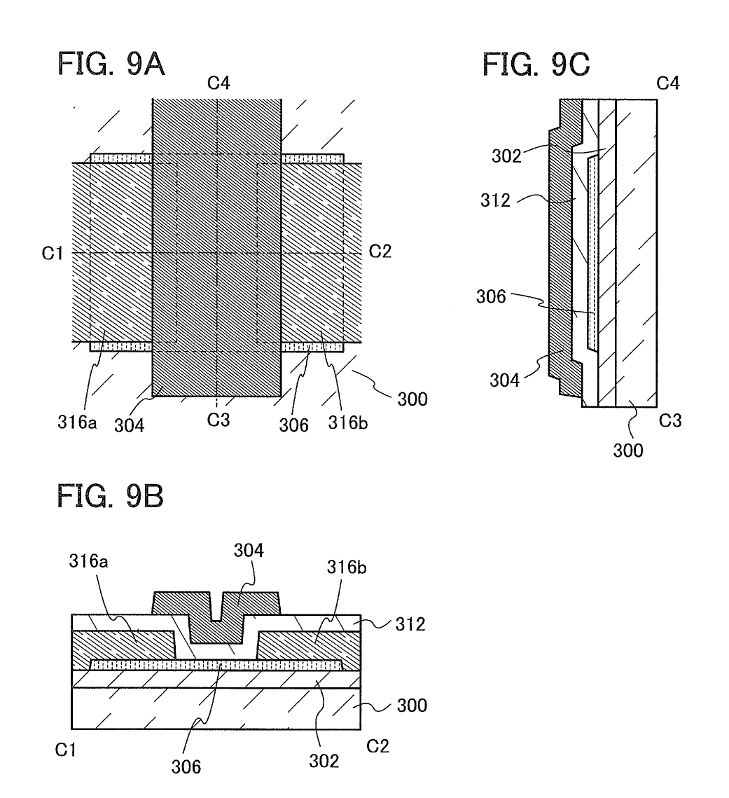

Next, a transistor having a structure different from those of the transistors illustrated in FIGS. 7A to 7C and FIGS. 8A to 8C will be described with reference to FIGS. 9A to 9C.

FIG. 9A is a top view of a transistor according to one embodiment of the present invention. FIG. 9B is a cross-sectional view taken along dashed-dotted line C1-C2 in FIG. 9A. FIG. 9C is a cross-sectional view along dashed-dotted line C3-C4 of FIG. 9A. Note that for simplicity, a gate insulating film 312 and the like are not shown in FIG. 9A.

FIG. 9B is a cross-sectional view of a transistor including a base insulating film 302 over a substrate 300, an oxide semiconductor film 306 over the base insulating film 302, a source electrode 316a and a drain electrode 316b which are over the oxide semiconductor film 306, the gate insulating film 312 over the oxide semiconductor film 306, the source electrode 316a, and the drain electrode 316b, and a gate electrode 304 which is over the gate insulating film 312 and overlaps with the oxide semiconductor film 306. Note that FIG. 9B illustrates a structure including the base insulating film 302; however, one embodiment of the present invention is not limited thereto. For example, a structure without the base insulating film 302 may be employed.

The description of the oxide semiconductor film 106 is referred to for the oxide semiconductor film 306.

The description of the substrate 100 is referred to for the substrate 300.

For the base insulating film 302, an insulating film similar to that for the protective insulating film 118 may be used. Note that in the case where the stacked film which is described as an example of the protective insulating film 118 is employed for the base insulating film 302, the order of stacking films may be reversed.

The base insulating film 302 is preferably flat. Specifically, the base insulating film 302 is made to have an average surface roughness (Ra) of 1 nm or less, 0.3 nm or less, or 0.1 nm or less.

Note that Ra is obtained by expanding, into three dimensions, arithmetic mean surface roughness that is defined by JIS B 0601: 2001 (ISO4287:1997) so as to be able to apply it to a curved surface. Ra can be expressed as “an average value of the absolute values of deviations from a reference surface to a designated surface” and is defined by Formula (2).

$$Ra = \frac{1}{{S}_{0}} {\int }_{y 1}^{y 2} {\int }_{x 1}^{x 2} \vert f ( x , y ) - {Z}_{0} \vert d x d y \qquad [ Formula 2 ]$$

Here, the specific surface is a surface that is a target of roughness measurement, and is a quadrilateral region specified by four points represented by the coordinates (x₁,y₁,f(x₁,y₁)), (x₁,y₂,f(x₁,y₂)), (x₂,y₁,f(x₂,y₁)), and (x₂,y₂,f(x₂,y₂)). Moreover, Sₒ represents the area of a rectangle which is obtained by projecting the specific surface on the xy plane, and Z₀ represents the height of the reference surface (the average height of the specific surface). Ra can be measured using an atomic force microscope (AFM).

It is preferred that the base insulating film 302 contain excess oxygen.

The description of the source electrode 116a and the drain electrode 116b are referred to for the source electrode 316a and the drain electrode 316b.

Note that a structure in which the source electrode 316a and the drain electrode 316b are in contact with a bottom surface of the oxide semiconductor film 306 may be employed.

For the gate insulating film 312, an insulating film similar to that for the gate insulating film 112 may be used.

The description of the gate electrode 104 is referred to for the gate electrode 304.

Note that, although not illustrated, a back gate electrode may be provided under the base insulating film 302 of the transistor illustrated in FIGS. 9A to 9C. The description of the back gate electrode 114 is referred to for the back gate electrode.

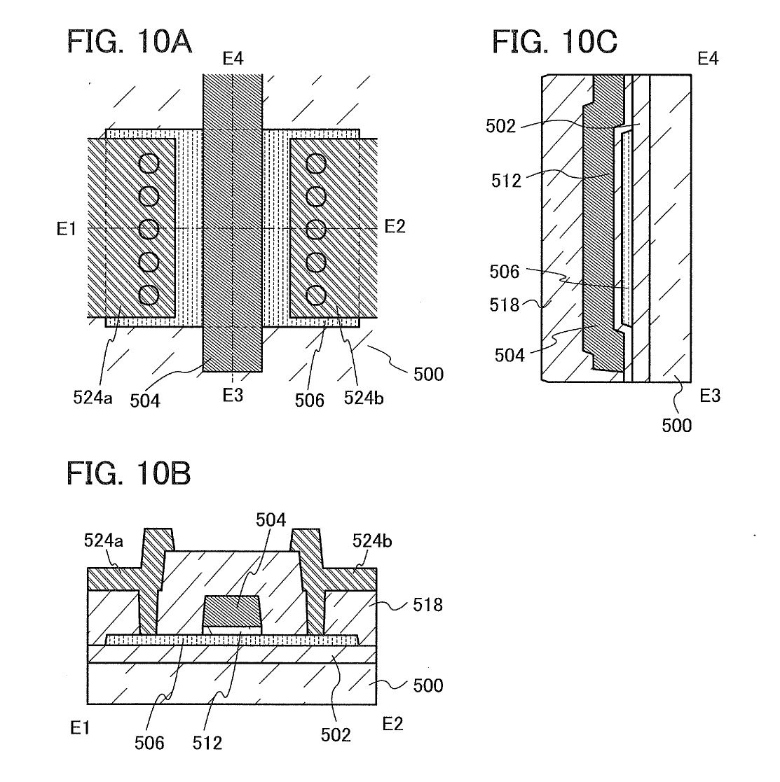

Next, a transistor having a structure different from those of the transistors illustrated in FIGS. 7A to 7C, FIGS. 8A to 8C, and FIGS. 9A to 9C, will be described with reference to FIGS. 10A to 10C.

FIG. 10A is a top view of a transistor according to one embodiment of the present invention. FIG. 10B is a cross-sectional view taken along dashed-dotted line E1-E2 in FIG. 10A. FIG. 10C is a cross-sectional view taken along dashed-dotted line E3-E4 in FIG. 10A. Note that for simplicity, a gate insulating film 512 and the like are not illustrated in FIG. 10A.

FIG. 10B is a cross-sectional view of a transistor including a base insulating film 502 over a substrate 500, an oxide semiconductor film 506 over the base insulating film 502, the gate insulating film 512 over the oxide semiconductor film 506, a gate electrode 504 which is over the gate insulating film 512 and overlaps with the oxide semiconductor film 506, and an interlayer insulating film 518 over the oxide semiconductor film 506 and the gate electrode 504. Note that FIG. 10B illustrates a structure including the base insulating film 502; however, one embodiment of the present invention is not limited thereto. For example, a structure without the base insulating film 502 may be employed.

In the cross-sectional view in FIG. 10B, openings reaching the oxide semiconductor film 506 are formed in the interlayer insulating film 518, and a wiring 524a and a wiring 524b provided over the interlayer insulating film 518 are in contact with the oxide semiconductor film 506 through the openings.

Note that although the gate insulating film 512 is provided only in a region overlapping with the gate electrode 504 in FIG. 10B, one embodiment of the present invention is not limited to this structure. For example, the gate insulating film 512 may be provided so as to cover the oxide semiconductor film 506. Alternatively, a sidewall insulating film may be provided in contact with a side surface of the gate electrode 504.

In the case of providing the sidewall insulating film in contact with the side surface of the gate electrode 504, it is preferred that, in the oxide semiconductor film 506, a region overlapping with the sidewall insulating film have lower resistance than a region overlapping with the gate electrode 504. For example, in the oxide semiconductor film 506, a region not overlapping with the gate electrode 504 may contain an impurity that reduces the resistance of the oxide semiconductor film 506. Alternatively, the resistance of the region may be reduced by defects. In the oxide semiconductor film 506, the region overlapping with the sidewall insulating film has lower resistance than the region overlapping with the gate electrode 504; thus, the region serves as a lightly doped drain (LDD) region. With the LDD regions of the transistor, drain induced barrier lower (DIBL) and hot-carrier degradation can be suppressed. Note that in the oxide semiconductor film 506, the region overlapping with the sidewall insulating film may serve also as an offset region. Also with the offset region of the transistor, DIBL and hot-carrier degradation can be suppressed.

The description of the oxide semiconductor film 106 is referred to for the oxide semiconductor film 506.

The description of the substrate 100 is referred to for the substrate 500.

For the base insulating film 502, an insulating film similar to that for the base insulating film 302 may be used.

An insulating film similar to that for the gate insulating film 112 is used as the gate insulating film 512.

The description of the gate electrode 104 is referred to for the gate electrode 504.

The interlayer insulating film 518 may be formed of a single layer or a stacked layer using an insulating film containing one or more of aluminum oxide, magnesium oxide, silicon oxide, silicon oxynitride, gallium oxide, germanium oxide, yttrium oxide, zirconium oxide, lanthanum oxide, neodymium oxide, hafnium oxide, and tantalum oxide.

The wiring 524a and the wiring 524b can be formed to have a single-layer or a stacked-layer structure of a simple substance selected from Al, Ti, Cr, Co, Ni, Cu, Y, Zr, Mo, Ag, Ta, and W; a nitride containing one or more kinds of the above substances; an oxide containing one or more kinds of the above substances; or an alloy containing one or more kinds of the above substances. Note that the wiring 524a and the wiring 524b may have the same composition or different compositions.

Note that, although not illustrated, a back gate electrode may be provided under the base insulating film 502 of the transistor illustrated in FIGS. 10A to 10C. The description of the back gate electrode 114 is referred to for the back gate electrode.

In the transistor illustrated in FIGS. 10A to 10C, a region where the gate electrode 504 overlaps with another wiring and electrode is small; therefore, parasitic capacitance is unlikely to be generated. Accordingly, the switching characteristics of the transistor can be improved. Moreover, the channel length of the transistor is determined by the width of the gate electrode 504; therefore, a miniaturized transistor having a short channel length is manufactured easily.

The transistors illustrated in FIGS. 7A to 7C, FIGS. 8A to 8C, FIGS. 9A to 9C, and FIGS. 10A to 10C each include, as an oxide semiconductor film, the In—Zn oxide film with a high degree of crystallinity described in the above embodiment. Thus, the transistors have stable electric characteristics. Note that any of the transistors described in this embodiment is applied to a semiconductor device such as a display device, a memory device, or a CPU, which enables a highly reliable semiconductor device to be formed.

This embodiment can be used in combination with any of the other embodiments and example.

### Embodiment 5

In this embodiment, a display device to which any of the transistors described in the above embodiments is applied will be described.

As a display element provided in the display device, a liquid crystal element (also referred to as a liquid crystal display element), a light-emitting element (also referred to as a light-emitting display element) or the like can be used. A light-emitting element includes, in its category, an element whose luminance is controlled by current or voltage, and specifically an inorganic electroluminescent (EL) element, an organic EL element, and the like. Furthermore, a display medium whose contrast is changed by an electric effect, such as electronic ink, can be used as the display element. In this embodiment, a display device including an EL element and a display device including a liquid crystal element will be described as examples of the display device.

Note that the display device of the present embodiment includes in its category a panel in which a display element is sealed, and a module in which an IC such as a controller or the like is mounted on the panel.

The display device in this embodiment means an image display device, a display device, or a light source (including a lighting device). The display device includes any of the following modules in its category: a module provided with a connector such as an FPC or TCP; a module in which a printed wiring board is provided at the end of TCP; and a module in which an integrated circuit (IC) is mounted directly on a display element by a COG method.

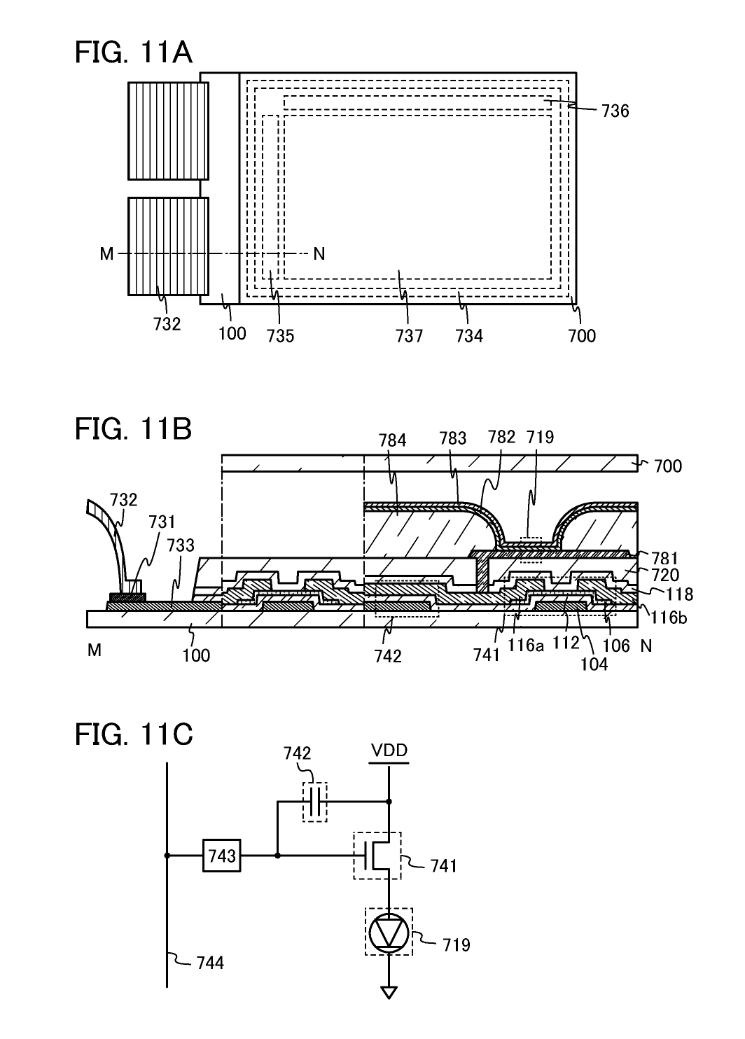

FIGS. 11A and 11B are a top view and a cross-sectional view illustrating an example of a display device using an EL element, and FIG. 11C is a circuit diagram of a pixel thereof.

FIG. 11A is a top view of a display device using an EL element. The display device using an EL element includes a substrate 100, a substrate 700, a sealant 734, a driver circuit 735, a driver circuit 736, a pixel 737, and an FPC 732. The sealant 734 is provided between the substrate 100 and the substrate 700 so as to surround the pixel 737, the driver circuit 735 and the driver circuit 736. Note that the driver circuit 735 and/or the driver circuit 736 may be provided outside the sealant 734.

FIG. 11B is a cross-sectional view of the display device using an EL element taken along dashed-dotted line M-N in FIG. 11A. The FPC 732 is connected to a wiring 733 via a terminal 731. Note that the wiring 733 is formed in the same layer as the gate electrode 104.

Note that FIG. 11B shows an example where a transistor 741 and a capacitor 742 are provided in the same plane. With such a structure, the capacitor 742 can be formed in the same plane as a gate electrode, a gate insulating film, and a source electrode (drain electrode), which are included in the transistor 741. When the transistor 741 and the capacitor 742 are provided in the same plane in this manner, the number of manufacturing steps of the display device can be reduced; thus, the productivity can be increased.

In the example of FIG. 11B, the transistor illustrated in FIGS. 7A to 7C is used as the transistor 741. Therefore, for components of the transistor 741, which are not particularly mentioned below, the description in the above embodiments is referred to.

An insulating film 720 is provided over the transistor 741 and the capacitor 742.

Here, an opening reaching the source electrode 116a of the transistor 741 is provided in the insulating film 720 and the protective insulating film 118.

An electrode 781 is provided over the insulating film 720. The electrode 781 is connected to the source electrode 116a of the transistor 741 through an opening provided in the insulating film 720 and the protective insulating film 118.

A partition 784 having an opening reaching the electrode 781 is provided over the electrode 781.

A light-emitting layer 782 in contact with the electrode 781 through the opening provided in the partition 784 is provided over the partition 784.

An electrode 783 is provided over the light-emitting layer 782.

A region where the electrode 781, the light-emitting layer 782, and the electrode 783 overlap with one another serves as the light-emitting element 719.

Note that description of the protective insulating film 118 is referred to for the insulating film 720. Alternatively, a resin film of a polyimide resin, an acrylic resin, an epoxy resin, a silicone resin, or the like may be used.

The light-emitting layer is not limited to a single layer, and may be a stack of plural kinds of light-emitting layers and the like. For example, a structure in which a first intermediate layer, a first light-emitting layer, a second intermediate layer, a second light-emitting layer, a third intermediate layer, a third light-emitting layer, and a fourth intermediate layer are stacked in this order may be employed. In that case, when light-emitting layers emitting light of appropriate colors are used as the first light-emitting layer, the second light-emitting layer, and the third light-emitting layer, the light-emitting element 719 with a high color rendering property or higher emission efficiency can be formed.

White light may be obtained by stacking plural kinds of light-emitting layers. Although not illustrated in FIG. 11B, white light may be extracted through coloring layers.

Although the structure in which three light-emitting layers 782 and four intermediate layers are provided is shown as an example here, the number of light-emitting layers and the number of intermediate layers can be changed as appropriate without limitation thereto. For example, the light-emitting layer can be formed with only a first intermediate layer, a first light-emitting layer, a second intermediate layer, a second light-emitting layer, and a third intermediate layer. Alternatively, the light-emitting layer can be formed with only the first intermediate layer, the first light-emitting layer, the second intermediate layer, the second light-emitting layer, the third light-emitting layer, and the fourth intermediate layer with the third intermediate layer omitted.

In addition, the intermediate layer can be formed using a stacked-layer structure of a hole-injection layer, a hole-transport layer, an electron-transport layer, an electron-injection layer, or the like. Note that not all of these layers need to be provided as the intermediate layer. Any of these layers may be selected as appropriate to form the intermediate layer. Note that a plurality of layers having similar functions may be provided. Further, an electron-relay layer or the like may be added as appropriate as the intermediate layer, in addition to a carrier generation layer.

The electrode 781 can be formed using a conductive film having a transmitting property with respect to visible light. The phrase “having a transmitting property with respect to visible light” means that the average transmittance of light in a visible light region (for example, a wavelength range from 400 nm to 800 nm) is higher than or equal to 70%, particularly higher than or equal to 80%.

As the electrode 781, for example, the In—Zn oxide film with a high degree of crystallinity described in the above embodiment may be used. Alternatively, as the electrode 781, for example, an oxide film such as an In—Zn—W oxide film, an In—Sn oxide film, an In oxide film, a Zn oxide film, or a Sn oxide film can be used. The above oxide film may contain a minute amount of Al, Ga, Sb, F, or the like. Further, a metal thin film having a thickness which enables light to be transmitted (preferably, approximately 5 nm to 30 nm) can also be used. For example, an Ag film, an Mg film, or an Ag—Mg alloy film with a thickness of 5 nm may be used.

The electrode 781 is preferred to be a film which efficiently reflects visible light. For example, a film containing lithium, aluminum, titanium, magnesium, lanthanum, silver, silicon, or nickel can be used as the electrode 781.

The electrode 783 can be formed using any of the films for the electrode 781. Note that when the electrode 781 has a transmitting property with respect to visible light, it is preferred that the electrode 783 efficiently reflects visible light. When the electrode 781 efficiently reflects visible light, it is preferred that the electrode 783 has a transmitting property with respect to visible light.

Positions of the electrode 781 and the electrode 783 are not limited to the structure illustrated in FIG. 11B, and the electrode 781 and the electrode 783 may be replaced with each other. It is preferred to use a conductive film having a high work function for the electrode which serves as an anode and a conductive film having a low work function for the electrode which serves as a cathode. Note that in the case where a carrier generation layer is provided in contact with the anode, a variety of conductive films can be used for the anode regardless of their work functions.

Note that description of the protective insulating film 118 is referred to for the partition 784. Alternatively, a resin film of a polyimide resin, an acrylic resin, an epoxy resin, a silicone resin, or the like may be used.

The transistor 741 connected to the light-emitting element 719 has stable electrical characteristics. Therefore, a display device having high display quality can be provided.

FIG. 11C illustrates an example of a circuit diagram of a pixel in a display device using an EL element. The pixel of the display device using an EL element includes a switching element 743, the transistor 741, the capacitor 742, and the light-emitting element 719.

A gate of the transistor 741 is electrically connected to one terminal of the switching element 743 and one terminal of the capacitor 742. A source of the transistor 741 is electrically connected to one terminal of the light-emitting element 719. A drain of the transistor 741 is electrically connected to the other terminal of the capacitor 742 and is supplied with a power supply potential VDD. The other terminal of the switching element 743 is electrically connected to a signal line 744. The other terminal of the light-emitting element 719 is supplied with a fixed potential. Note that the fixed potential is a ground potential GND or lower.

As the switching element 743, it is preferred to use a transistor. With a transistor, the area of a pixel can be reduced, so that a display device having a high resolution can be obtained. Moreover, as the switching element 743, any of the transistors including an oxide semiconductor film described in the above embodiment may be used. With use of the transistor as the switching element 743, the switching element 743 can be formed in the same process as the transistor 741; thus, the productivity of the display device can be improved.

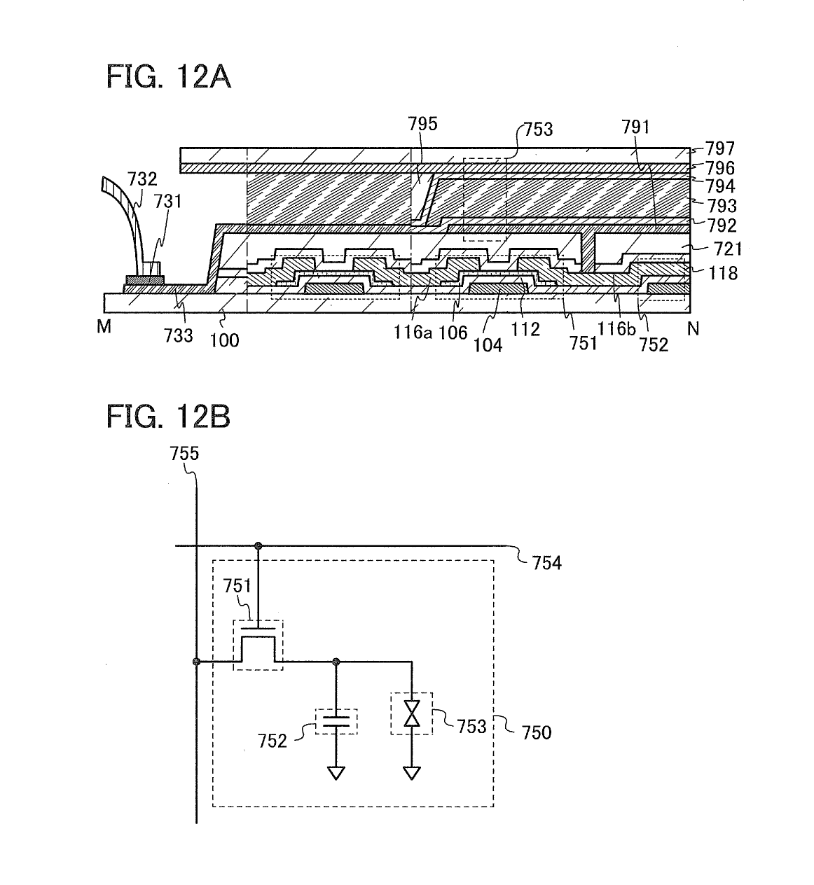

Next, the display device including a liquid crystal element is described. FIG. 12A is a cross-sectional view illustrating an example of a display device using a liquid crystal element, and FIG. 12B is a circuit diagram of a pixel thereof.

Note that a top view of the display device using a liquid crystal element is substantially same as that of the display device using an EL element. FIG. 12A is a cross-sectional view of the display device using a liquid crystal element taken along dashed-dotted line M-N in FIG. 11A. In FIG. 12A, the FPC 732 is connected to the wiring 733 via the terminal 731. The wiring 733 is formed in the same layer as the electrode 791.

Note that FIG. 12A shows an example where the transistor 751 and the capacitor 752 are provided in the same plane. With such a structure, the capacitor 752 can be formed in the same plane as a gate electrode, a gate insulating film, and a source electrode (drain electrode), which are included in the transistor 751. When the transistor 751 and the capacitor 752 are provided in the same plane in this manner, the number of manufacturing steps of the display device can be reduced; thus, the productivity can be increased.

Note that, as the transistor 751, any of the transistors described in the above embodiments can be used. In the example of FIG. 12A, the transistor illustrated in FIGS. 7A to 7C is used. Therefore, for components of the transistor 751, which are not particularly mentioned below, the description in the above embodiments is referred to.

An insulating film 721 is provided over the transistor 751 and the capacitor 752.

Here, an opening reaching the drain electrode 116b of the transistor 751 is provided in the insulating film 721 and the protective insulating film 118.

An electrode 791 is provided over the insulating film 721. The electrode 791 is in contact with the drain electrode 116b of the transistor 751 through the opening provided in the insulating film 721 and the protective insulating film 118.

An insulating film 792 serving as an alignment film is provided over the electrode 791.

A liquid crystal layer 793 is provided over the insulating film 792.

An insulating film 794 serving as an alignment film is provided over the liquid crystal layer 793.

A spacer 795 is provided over the insulating film 794.

An electrode 796 is provided over the spacer 795 and the insulating film 794.

A substrate 797 is provided over the electrode 796.

Note that description of the protective insulating film 118 is referred to for the insulating film 721. Alternatively, a resin film of a polyimide resin, an acrylic resin, an epoxy resin, a silicone resin, or the like may be used.

For the liquid crystal layer 793, a thermotropic liquid crystal, a low-molecular liquid crystal, a polymer liquid crystal, a polymer-dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Note that as the liquid crystal layer 793, a liquid crystal exhibiting a blue phase may be used. In that case, the insulating films 792 and 794 serving as an alignment film are not necessarily provided.

The electrode 791 can be formed using a conductive film having a transmitting property with respect to visible light.

As the electrode 791, for example, the In—Zn oxide film with a high degree of crystallinity described in the above embodiment may be used. Alternatively, as the electrode 791, an oxide film such as an In—Zn—W-based oxide film, an In—Sn-based oxide film, an In-based oxide film, a Zn-based oxide film, or a Sn-based oxide film may be used. The above oxide film may contain a minute amount of Al, Ga, Sb, F, or the like. Further, a metal thin film having a thickness which enables light to be transmitted (preferably, approximately 5 nm to 30 nm) can also be used.

Alternatively, the electrode 791 is preferred to be a film which efficiently reflects visible light. For example, a film containing aluminum, titanium, chromium, copper, molybdenum, silver, tantalum, or tungsten can be used as the electrode 791.

The electrode 796 can be formed using any of the films for the electrode 791. Note that when the electrode 791 has a transmitting property with respect to visible light, it is preferable that the electrode 796 efficiently reflect visible light. When the electrode 791 efficiently reflects visible light, it is in some cases preferred that the electrode 796 has a transmitting property with respect to visible light.

Positions of the electrode 791 and the electrode 796 are not limited to the structure illustrated in FIG. 12A, and the electrode 791 and the electrode 796 may be replaced with each other.

Each of the insulating films 792 and 794 may be formed using an organic compound or an inorganic compound.

The spacer 795 may be formed using an organic compound or an inorganic compound. Note that the spacer 795 can have a variety of shapes such as a columnar shape and a spherical shape.

A region where the electrode 791, the insulating film 792, the liquid crystal layer 793, the insulating film 794, and the electrode 796 overlap with one another serves as the liquid crystal element 753.

For the substrate 797, a glass substrate, a resin substrate, a metal substrate, or the like can be used. The substrate 797 may have flexibility.

FIG. 12B is a circuit diagram illustrating a structure example of the pixel of the display device using a liquid crystal element. A pixel 750 shown in FIG. 12B includes the transistor 751, the capacitor 752, and the liquid crystal element 753. Note that the liquid crystal element is an element in which liquid crystal is injected between a pair of electrodes.

One of a source and a drain of the transistor 751 is electrically connected to a signal line 755, and a gate of the transistor 751 is electrically connected to a scan line 754.

One of electrodes of the capacitor 752 is electrically connected to the other of the source and the drain of the transistor 751, and the other of the electrodes of the capacitor 752 is electrically connected to a wiring for supplying a common potential.

One of electrodes of the liquid crystal element 753 is electrically connected to the other of the source and the drain of the transistor 751, and the other of the electrodes of the liquid crystal element 753 is electrically connected to a wiring for supplying a common potential. Note that the common potential supplied to the other of the electrodes of the liquid crystal element 753 may be different from the common potential supplied to the wiring electrically connected to the other of the electrodes of the capacitor 752.

This embodiment can be implemented in appropriate combination with any of the other embodiments and example.

### Embodiment 6

In this embodiment, examples of electronic devices including any of the semiconductor devices described in the above embodiment will be described.

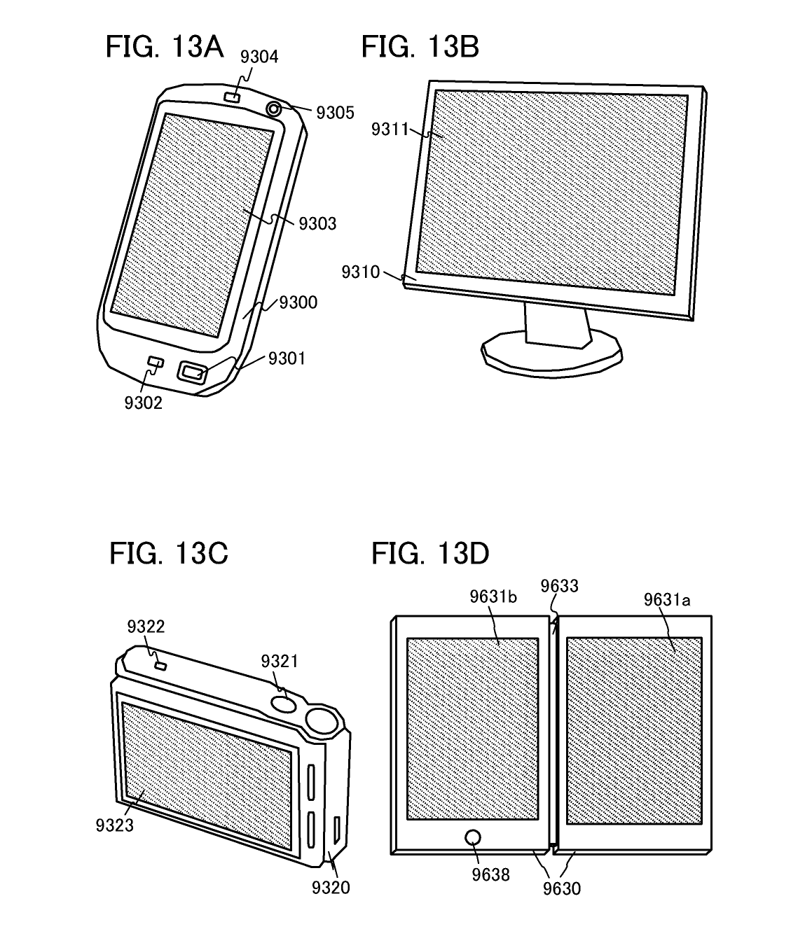

FIG. 13A illustrates a portable information terminal. The portable information terminal illustrated in FIG. 13A includes a housing 9300, a button 9301, a microphone 9302, a display portion 9303, a speaker 9304, and a camera 9305, and has a function as a mobile phone. One embodiment of the present invention can be applied to an arithmetic unit, a wireless circuit, or a memory circuit in a main body. Alternatively, one embodiment of the present invention can be applied to the display portion 9303.

FIG. 13B illustrates a display which includes a housing 9310 and a display portion 9311. One embodiment of the present invention can be applied to an arithmetic unit, a wireless circuit, or a memory circuit in a main body. Alternatively, one embodiment of the present invention can be applied to the display portion 9311.

FIG. 13C illustrates a digital still camera, which includes a housing 9320, a button 9321, a microphone 9322, and a display portion 9323. One embodiment of the present invention can be applied to an arithmetic unit, a wireless circuit, or a memory circuit in a main body. Alternatively, one embodiment of the present invention can be applied to the display portion 9323.

FIG. 13D illustrates a double-foldable portable information terminal, which includes a housing 9630, a display portion 9631a, a display portion 9631b, a hinge 9633, and an operation switch 9638. One embodiment of the present invention can be applied to an arithmetic unit, a wireless circuit, or a memory circuit in a main body. Alternatively, one embodiment of the present invention can be applied to the display portion 9631a and the display portion 9631b.

Part or whole of the display portion 9631a and/or the display portion 9631b can function as a touch panel. By touching an operation key displayed on the touch panel, a user can input data, for example.

With use of a semiconductor device according to one embodiment of the present invention, an electronic device with stable characteristics can be provided.

This embodiment can be implemented in appropriate combination with any of the other embodiments and example.

### Example 1

In this example, results of examination which was conducted on crystal states of a sputtering target including a polycrystalline In—Zn oxide and an In—Zn oxide film will be described.

Sample which is a sputtering target was formed by the method described in Embodiment 1. The molar ratio of an In₂O₃ powder to a ZnO powder was set to 1:1.

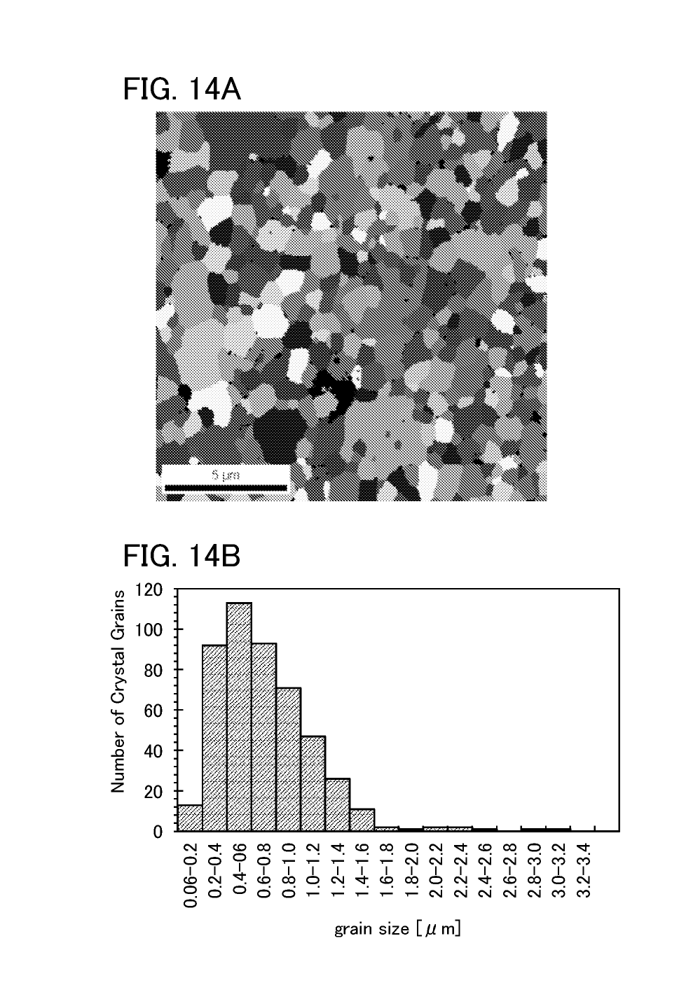

FIG. 14A shows a crystal grain map of Sample, and FIG. 14B shows a histogram of grain sizes thereof. A square region of 16 μm×16 μm was measured, and the step was 0.06 μm. Under the above conditions, crystal grains whose sizes are approximately less than 0.06 μm cannot be counted as crystal grains. Thus, a crystal grain which is measured to be less than 0.2 μm is practically a crystal grain whose size is greater than or equal to 0.06 μm and less than 0.2 μm.

Table 1 shows the grain sizes of crystal grains of Sample obtained by EBSD and the number thereof.

TABLE 1

| Grain Size [μm] | Number of Crystal Grains |
|---|---|
| 0.06-0.2 | 13 |
| 0.2-0.4 | 92 |
| 0.4-06 | 113 |
| 0.6-0.8 | 93 |
| 0.8-1.0 | 71 |
| 1.0-1.2 | 47 |
| 1.2-1.4 | 26 |
| 1.4-1.6 | 11 |
| 1.6-1.8 | 2 |
| 1.8-2.0 | 1 |
| 2.0-2.2 | 2 |
| 2.2-2.4 | 2 |
| 2.4-2.6 | 1 |
| 2.6-2.8 | 0 |
| 2.8-3.0 | 1 |
| 3.0-3.2 | 1 |
| 3.2-3.4 | 0 |
| 3.4 or more | 0 |

Note that the average grain size of crystal grains in Sample was 0.71 μm. Further, the proportion of crystal grains which were greater than or equal to 0.06 μm and less than 1 μm in Sample was 80.3%, that of crystal grains which were greater than or equal to 0.06 μm and less than 0.8 μm in Sample was 65.3%, that of crystal grains which were greater than or equal to 0.06 μm and less than 0.6 μm in Sample was 45.8%, and that of crystal grains which were greater than or equal to 0.06 μm and less than 0.4 μm in Sample was 22.1%.

Next, an In—Zn oxide film was formed with use of Sample as a sputtering target.

The In—Zn oxide film was formed to a thickness of 100 nm over a quartz substrate. For film formation, a DC magnetron sputtering method was employed. The other film formation conditions were as follows: the power was 100 W; the pressure was 0.4 Pa; the substrate heating temperature was 200° C.; and the flow rate of an oxygen gas was 15 sccm.

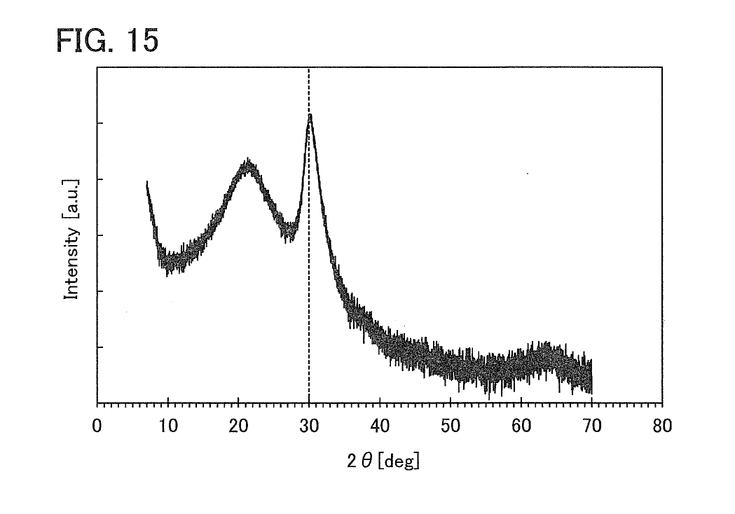

Next, a crystal state of the In—Zn oxide film formed with use of Sample as a sputtering target was examined with an X-ray diffraction (XRD) apparatus. The measurement was conducted by an out-of-plane method (2θ/ω scan). The result is shown in FIG. 15.

According to FIG. 15, there is a peak around 30° in the In—Zn oxide film. Note that between 20° to 25°, peaks attributed to the quartz substrate appear. Thus, it is found that in the In—Zn oxide film formed with use of Sample as a sputtering target, crystals are orientated in a specific direction.

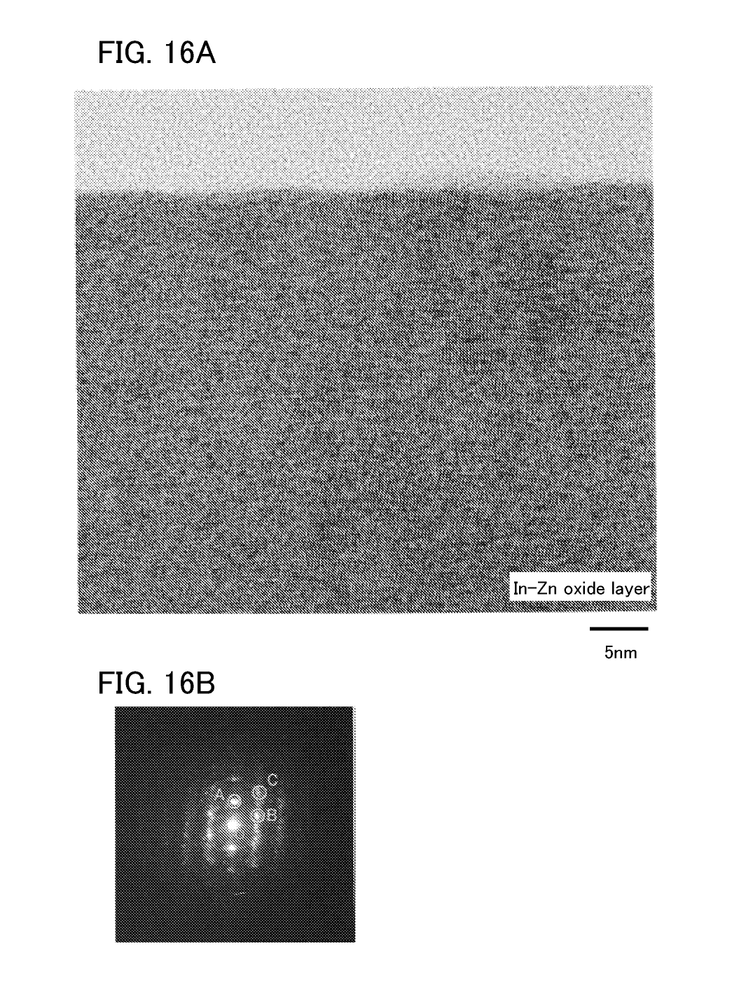

Next, atomic arrangement in a cross section of the In—Zn oxide film was observed (see FIG. 16A). For the observation of atomic arrangement seen in a cross section, Hitachi H-9000NAR transmission electron microscope (TEM) was used, and a high resolution TEM image (a combined analysis image of a bright-field image and a diffraction image) was observed. Note that the accelerating voltage was 300 kV.

According to FIG. 16A, the In—Zn oxide film has regular atomic arrangement parallel to its top surface. In the observation region, electron beam diffraction was measured, and the diffraction pattern is shown in FIG. 16B. For the measurement of electron beam diffraction, Hitachi HF-2000 field-emission transmission electron microscope was used. Note that the accelerating voltage was 200 kV.

The diffraction pattern in FIG. 16B indicates that the spacing of lattice planes (also referred to as d-spacing) in a diffraction spot A showing the highest intensity diffraction is 0.295 nm, the d-spacing in a diffraction spot B is 0.266 nm, and the d-spacing in a diffraction spot C is 0.165 nm. Further, angles made by any of the diffraction spot A, the diffraction spot B, and the diffraction spot C with a spot O (a transmitted wave or an origin) as a base point were measured; the angle ∠AOB was 69°, the angle ∠AOC was 35°, and ∠BOC was 34°.

Table 2 shows a relation between crystal planes of the In—Zn oxide and d-spacing. Note that in Table 2, data about an In₂ZnO₄ trigonal crystal and an In₂Zn₂O₅ hexagonal crystal are shown.

TABLE 2

| | |
|---|---|
| In₂ZnO₄ trigonal crystal | In₂Zn₂O₅ hexagonal crsytal |

| h k l | d-spacing [nm] | h k l | d-spacing [nm] |
|---|---|---|---|
| 1 0 0 | 0.299 | 1 0 0 | 0.292 |
| 0 0 9 | 0.292 | 0 0 8 | 0.288 |
| 1 0 3 | 0.283 | 1 0 4 | 0.26 |
| 1 0 6 | 0.247 | 1 1 0 | 0.169 |
| 1 0 9 | 0.209 | 1 0 12 | 0.161 |
| 1 0 12 | 0.177 | 1 1 8 | 0.146 |
| 1 1 0 | 0.173 | | |
| 1 1 9 | 0.149 | | |

Further, Table 3 shows angles formed between two kinds of crystal planes in each case of the In₂ZnO₄ trigonal crystal and the In₂Zn₂O₅ hexagonal crystal.

TABLE 3

| In₂ZnO₄ trigonal crystal | In₂Zn₂O₅ hexagonal crystal |
|---|---|
| ∠0 0 9 − 1 0 3 = 71.1° | ∠0 0 8 − 1 0 4 = 63.2° |
| ∠0 0 9 − 1 0 6 = 55.7° | ∠0 0 8 − 1 0 12 = 33.4° |
| ∠0 0 9 − 1 0 9 = 44.3° | ∠1 0 4 − 1 0 12 = 29.8° |
| ∠0 0 9 − 1 0 12 = 36.2° | ∠0 0 8 − 1 1 0 = 90.0° |
| ∠0 0 9 − 1 0 15 = 30.4° | ∠0 0 8 − 1 1 8 = 59.7° |
| ∠0 0 9 − 1 1 0 = 90.0° | ∠1 1 0 − 1 1 8 = 30.3° |
| ∠0 0 9 − 1 1 9 = 59.4° | |

Note that for formation of Table 2 and Table 3, JCPDS card No. 20-1442, Y. Yan et. al, Appl. Phys. Lett. 73, 2585 (1998), and J. L. F. Da Silva et. at, Phys. Rev. Lett. 100, 255501 (2008) were referred to.

According to the cross section image in FIG. 16A and the diffraction pattern in FIG. 16B, in the case where the In—Zn oxide film is the In₂ZnO₄ trigonal crystal, the diffraction spot A indicates a (0 0 9) plane, the diffraction spot B indicates a (1 0 3) plane, and the diffraction spot C indicates a (1 0 12) plane. Further, in the case where the In—Zn oxide film is the In₂Zn₂O₅ hexagonal crystal, the diffraction spot A indicates a (0 0 8) plane, the diffraction spot B indicates a (1 0 4) plane, and the diffraction spot C indicates a (1 0 12) plane. Thus, the diffraction spot A showing the highest intensity diffraction indicates a (0 0 9) plane or a (0 0 8) plane, which indicates that the In—Zn oxide film has c-axis alignment in both the case where the In—Zn oxide film includes a hexagonal crystal and the case where the In—Zn oxide film includes a trigonal crystal regarded as a hexagonal crystal.

According to this example, an In—Zn oxide film formed using a sputtering target including a polycrystalline In—Zn oxide with a small average grain size has high crystallinity.

This application is based on Japanese Patent Application serial no. 2012-160570 filed with Japan Patent Office on Jul. 19, 2012, the entire contents of which are hereby incorporated by reference.

What is claimed is:

1. A sputtering target comprising:
a polycrystalline In—Zn oxide comprising a plurality of crystal grains,
wherein an average grain size of the plurality of crystal grains is greater than or equal to 0.06 μm and less than or equal to 3 μm.

2. The sputtering target according to claim 1, wherein a proportion of crystal grains whose grain size is greater than or equal to 0.06 μm and less than 1 μm is higher than or equal to 20%.

3. The sputtering target according to claim 1, wherein the plurality of crystal grains are trigonal crystals or hexagonal crystals.

4. The sputtering target according to claim 1, wherein the plurality of crystal grains each have a cleavage plane.

5. A method for using a target comprising the steps of:
separating a plurality of particles charged positively from the target by subjecting the target to sputtering; and
depositing the plurality of particles repelling each other on a deposition surface,
wherein the target comprises a polycrystalline In—Zn oxide, and
wherein the plurality of particles have a flat plate shape.

6. The method for using a target according to claim 5, wherein the plurality of particles have crystallinity.

7. The method for using a target according to claim 5, wherein the plurality of particles each have a hexagonal cylinder shape.

8. The method for using a target according to claim 5, wherein the plurality of particles are generated by cleavage of the polycrystalline In—Zn oxide included in the target.

9. A method for using a target comprising the steps of:
separating a plurality of particles from the target by subjecting the target to sputtering;
positively charging the plurality of particles; and
depositing the plurality of particles repelling each other on a deposition surface,
wherein the target comprises a polycrystalline In—Zn oxide, and
wherein the plurality of particles have a flat plate shape.

10. The method for using a target according to claim 9, wherein the plurality of particles have crystallinity.

11. The method for using a target according to claim 9, wherein the plurality of particles each have a hexagonal cylinder shape.

12. The method for using a target according to claim 9, wherein the plurality of particles are generated by cleavage of the polycrystalline In—Zn oxide included in the target.

13. A method for forming an oxide film comprising the steps of:
separating a plurality of particles charged positively from a target by subjecting the target to collision of ions; and
depositing the plurality of particles on a deposition surface while repelling each other so that flat surfaces of the plurality of particles are attached to a region which is not positively charged,
wherein the plurality of particles have a flat plate shape, and
wherein the target comprises a polycrystalline In—Zn oxide.

14. The method for forming an oxide film according to claim 13, wherein the plurality of particles have crystallinity.

15. The method for forming an oxide film according to claim 13,
wherein the plurality of particles each have a hexagonal cylinder shape, and
wherein the hexagonal cylinder shape has c-axis aligned in a direction perpendicular to a hexagonal plane of the hexagonal cylinder.

16. The method for forming an oxide film according to claim 13, wherein the plurality of particles are generated by cleavage of the polycrystalline In—Zn oxide included in the target.

17. A method for forming an oxide film comprising the steps of:
separating a plurality of particles from a target by subjecting the target to collision of ions;
positively charging the plurality of particles; and
depositing the plurality of particles on a deposition surface while repelling each other so that flat surfaces of the plurality of particles are attached to a region which is not positively charged,
wherein the plurality of particles have a flat plate shape, and
wherein the target comprises a polycrystalline In—Zn oxide.

18. The method for forming an oxide film according to claim 17, wherein the plurality of particles have crystallinity.

19. The method for forming an oxide film according to claim 17,
wherein the plurality of particles each have a hexagonal cylinder shape, and
wherein the hexagonal cylinder shape has c-axis aligned in a direction perpendicular to a hexagonal plane of the hexagonal cylinder.

20. The method for forming an oxide film according to claim 17, wherein the plurality of particles are generated by cleavage of the polycrystalline In—Zn oxide included in the target.
